(19) United States
(12) Patent Application Publication
(10) Pub. No.: US 2026/0011625 A1
(43) Pub. Date: Jan. 8, 2026

(54) SEMICONDUCTOR DEVICE

(71) Applicant: FUJI ELECTRIC CO., LTD., Kawasaki-shi (JP)

(72) Inventor: Hiroyuki NOGAWA, Matsumoto-city (JP)

(73) Assignee: FUJI ELECTRIC CO., LTD., Kawasaki-shi (JP)

(21) Appl. No.: 19/249,856

(22) Filed: Jun. 25, 2025

Related U.S. Application Data
(63) Continuation of application No. PCT/JP2024/020728, filed on Jun. 6, 2024.

(30) Foreign Application Priority Data
Jul. 24, 2023 (JP) 2023-120094
Sep. 15, 2023 (JP) 2023-150332

(51) Int. Cl. H01L 23/492; H01L 23/00; H01L 23/049; H01L 23/373

(52) U.S. Cl. CPC H01L 23/4922; H01L 23/049; H01L 23/3735; H01L 24/32; H01L 24/48; H01L 24/73; H01L 2224/32225; H01L 2224/48175; H01L 2224/73265

(57) ABSTRACT

A semiconductor device includes an insulated circuit board having a lower surface, a heat dissipation base plate having a front surface that includes an arrangement region in which the lower surface of the insulated circuit board is arranged via solder and a solder region in which the solder spreads over the arrangement region, a plating film formed on the front surface of the heat dissipation base plate except for the solder region, and an alloy layer disposed between the solder and the heat dissipation base plate in the arrangement region. The alloy layer contains a solder component that is contained in the solder. In particular, in the semiconductor device, the plating film is formed on an entire surface of the heat dissipation base plate except for an opening region surrounding an outer periphery of the arrangement region where the insulated circuit board is arranged via the solder.

### CROSS-REFERENCE TO RELATED APPLICATIONS

This application is a continuation application of International Application PCT/JP2024/020728 filed on Jun. 6, 2024, which designated the U.S., which claims priority to Japanese Patent Application No. 2023-120094, filed on Jul. 24, 2023, and Japanese Patent Application No. 2023-150332, filed on Sep. 15, 2023, the entire contents of which are incorporated herein by reference.

### BACKGROUND OF THE INVENTION

### 1. Field of the Invention

The embodiments discussed herein relate to a semiconductor device.

### 2. Background of the Related Art

A semiconductor device includes a metal base and an insulating substrate provided on the metal base via solder (see, for example, Japanese Laid-open Patent Publication No. 2019-080014). As another example, a semiconductor device includes a collector lead frame and a semiconductor element provided on the collector lead frame via solder (for example, see Japanese Laid-open Patent Publication No. 2018-085360). In addition, a recess having a concave shape is formed on the upper surface of a base member, a plated layer is formed on the upper surface including the recess, and the lower surface of the base member and the upper surface on which the plated layer is formed are polished. Thus, the plated layer filling the recess of the base member functions as a penetrating electrode (see, for example, Japanese Laid-open Patent Publication No. 2013-055114). Furthermore, a copper plating film may be formed in a pattern formation region by electroless reduction plating using a resist pattern formed on a base substrate as a plating prevention film (see, for example, Japanese Laid-open Patent Publication No. 2012-140705). Moreover, a plating film may be peeled off by laser irradiation (see, for example, Japanese Laid-open Patent Publication No. H10-183382).

### SUMMARY OF THE INVENTION

According to an aspect of the present disclosure, there is provided a semiconductor device, including: a board having a lower surface; a heat dissipation base plate having a principal surface that includes an arrangement region in which the lower surface of the board is arranged via a solder, and a solder region in which the solder spreads over the arrangement region; a first plating film on the principal surface of the heat dissipation base plate, except for the solder region; and an alloy layer disposed between the solder and the heat dissipation base plate in the arrangement region, the alloy layer containing a solder component.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a cross-sectional view of a semiconductor device according to a first embodiment;

FIG. 2 is a plan view of a principal part of the semiconductor device according to the first embodiment (without a sealing member);

FIG. 3 is a flowchart illustrative of a method for manufacturing the semiconductor device according to the first embodiment;

FIG. 4 is a plan view illustrative of a manufacturing step (preparing a heat dissipation base plate) of a heat dissipation unit included in the method for manufacturing the semiconductor device according to the first embodiment;

FIG. 5 is a plan view illustrative of a manufacturing step (plating treatment) of the heat dissipation unit included in the method for manufacturing the semiconductor device according to the first embodiment;

FIG. 6 is a plan view illustrative of a manufacturing step (grinding process) of the heat dissipation unit included in the method for manufacturing the semiconductor device according to the first embodiment;

FIG. 7 is a cross-sectional view illustrative of the manufacturing step (grinding process) of the heat dissipation unit included in the method for manufacturing the semiconductor device according to the first embodiment;

FIG. 8 is a plan view illustrative of a manufacturing step (setting a mask) of the heat dissipation unit included in the method for manufacturing the semiconductor device according to the first embodiment;

FIG. 9 is a plan view illustrative of a manufacturing step (plating treatment) of the heat dissipation unit included in the method for manufacturing the semiconductor device according to the first embodiment;

FIG. 10 is a plan view illustrative of a manufacturing step (removing the mask) of the heat dissipation unit included in the method for manufacturing the semiconductor device according to the first embodiment;

FIG. 11 is a cross-sectional view illustrative of the manufacturing step (removing the mask) of the heat dissipation unit included in the method for manufacturing the semiconductor device according to the first embodiment;

FIG. 12 is a cross-sectional view illustrative of an arrangement step included in the method for manufacturing the semiconductor device according to the first embodiment;

FIG. 13 is a schematic cross-sectional view illustrative of the arrangement of atoms in the arrangement step included in the method for manufacturing the semiconductor device according to the first embodiment;

FIG. 14 is a cross-sectional view illustrative of a bonding step included in the method for manufacturing the semiconductor device according to the first embodiment;

FIG. 15 is a schematic cross-sectional view illustrative of the arrangement of atoms in the bonding step included in the method for manufacturing the semiconductor device according to the first embodiment;

FIG. 16 is a cross-sectional view illustrative of an arrangement step included in a method for manufacturing a semiconductor device taken as a reference example;

FIG. 17 is a schematic cross-sectional view illustrative of the arrangement of atoms in the arrangement step included in the method for manufacturing the semiconductor device taken as a reference example;

FIG. 18 is a first schematic cross-sectional view illustrative of the arrangement of atoms in a bonding step (at heating time) included in the method for manufacturing the semiconductor device taken as a reference example;

FIG. 19 is a second schematic cross-sectional view illustrative of the arrangement of atoms in the bonding step (at heating time) included in the method for manufacturing the semiconductor device taken as a reference example;

FIG. 20 is a third schematic cross-sectional view illustrative of the arrangement of atoms in the bonding step (at heating time) included in the method for manufacturing the semiconductor device taken as a reference example;

FIG. 21 is a cross-sectional view illustrative of the bonding step (after bonding) included in the method for manufacturing the semiconductor device taken as a reference example;

FIG. 22 is a cross-sectional view of a semiconductor device according to a second embodiment;

FIG. 23 is a rear perspective view of an insulated circuit board included in the semiconductor device according to the second embodiment;

FIG. 24 is a plan view of a principal part of a semiconductor device according to a third embodiment (without a sealing member);

FIG. 25 is a cross-sectional view of a semiconductor device according to a fourth embodiment;

FIG. 26 is a flowchart illustrative of a method for manufacturing the semiconductor device according to the fourth embodiment;

FIG. 27 is a cross-sectional view illustrative of a manufacturing step (plating treatment) of a heat dissipation unit included in the method for manufacturing the semiconductor device according to the fourth embodiment;

FIG. 28 is a cross-sectional view illustrative of the manufacturing step (thinning process) of the heat dissipation unit included in the method for manufacturing the semiconductor device according to the fourth embodiment;

FIG. 29 is a cross-sectional view illustrative of an arrangement step included in the method for manufacturing the semiconductor device according to the fourth embodiment;

FIG. 30 is a schematic cross-sectional view illustrative of the arrangement of atoms in the arrangement step included in the method for manufacturing the semiconductor device according to the fourth embodiment;

FIG. 31 is a cross-sectional view illustrative of a bonding step included in the method for manufacturing the semiconductor device according to the fourth embodiment; and

FIG. 32 is a schematic cross-sectional view illustrative of the arrangement of atoms in the bonding step included in the method for manufacturing the semiconductor device according to the fourth embodiment.

### DETAILED DESCRIPTION OF THE INVENTION

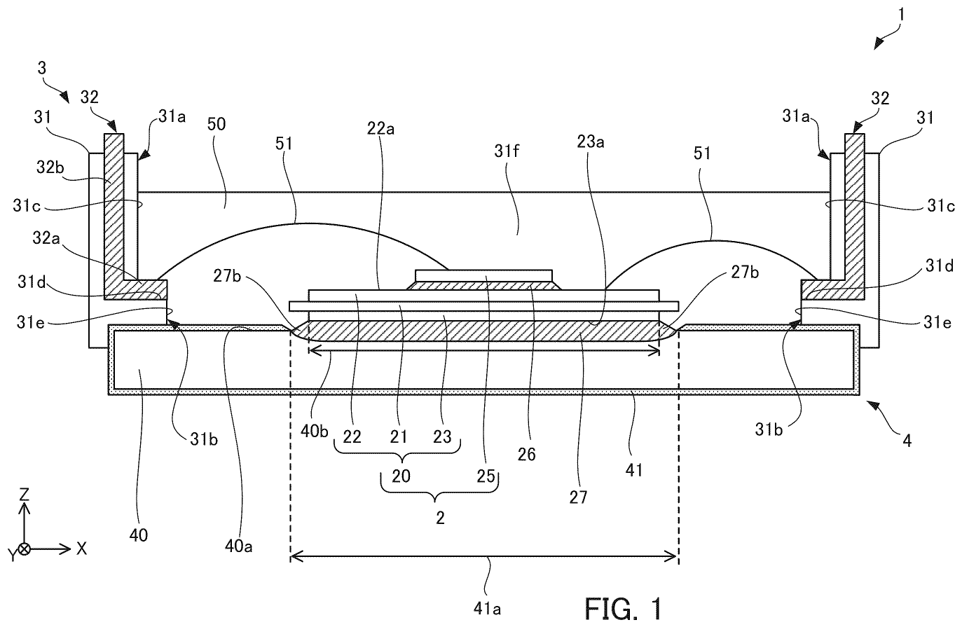

Hereinafter, the embodiments will be described with reference to the drawings. In the following description, a “front surface” or an “upper surface” indicates an X-Y plane facing the upper side (+Z direction) in a semiconductor device 1 of FIG. 1. Similarly, an “upside” indicates an upward direction (+Z direction) direction in the semiconductor device 1 of FIG. 1. A “back surface” or a “lower surface” indicates the X-Y plane facing the lower side (−Z direction) in the semiconductor device 1 of FIG. 1. Similarly, a “downside” indicates a downward direction (−Z direction) in the semiconductor device 1 of FIG. 1. These terms mean the same directions at need in the other drawings. “Highly placed” or “placed above” indicates an upward position (+Z direction) in the semiconductor device 1 of FIG. 1. Similarly, “placed low” or “placed below” indicates a downward position (−Z direction) in the semiconductor device 1 of FIG. 1. The terms “front surface”, “upper surface”, “upside” and “back surface”, “lower surface”, “downside” and “side surface” are simply used as expedient representation for specifying relative positional relationships, and do not limit the technical idea of the present disclosure. For example, the “upside” or the “downside” does not always mean the vertical direction with respect to the ground. That is, a direction indicated by the “upside” or the “downside” is not limited to the gravity direction. In addition, in the following description, a “main component” indicates a component contained at a rate of 80 vol % or more (in a case where a filler is contained, the filler is excluded). Furthermore, “approximately equal” means that two objects are in the range of ±10%. Moreover, “perpendicular”, “orthogonal”, or “parallel” means that an angle which one object forms with the other object is in the range of 90°±100 or 180°±100.

### First Embodiment

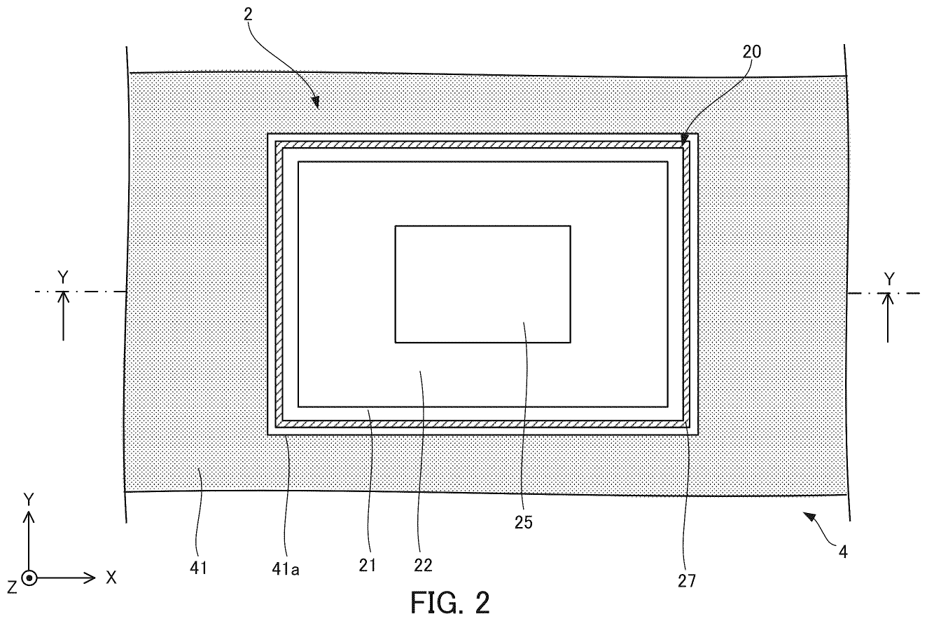

A semiconductor device will be described with reference to FIGS. 1 and 2. FIG. 1 is a cross-sectional view of a semiconductor device according to a first embodiment. FIG. 2 is a plan view of a principal part of the semiconductor device according to the first embodiment (without a sealing member). FIG. 2 is an enlarged view of a region including a semiconductor chip 25, with a sealing member 50 and wires 51 removed from a semiconductor device 1 of FIG. 1. FIG. 2 is an enlarged view of a principal part in a case 3 of FIG. 1, and thus the case 3 is not illustrated. FIG. 1 is a cross-sectional view taken along the dot-dash line Y-Y in FIG. 2 in a case where the case 3 is included.

As illustrated in FIG. 1, the semiconductor device 1 includes a semiconductor unit 2, a heat dissipation unit 4 having a front surface on which the semiconductor unit 2 is arranged, and a case 3 that is placed on an outer edge portion of the heat dissipation unit 4 and that houses the semiconductor unit 2. The inside of the case 3 of the semiconductor device 1 is sealed by the sealing member 50.

For example, the sealing member 50 is silicone gel. Furthermore, the sealing member 50 may be a thermosetting resin mixed with a filler. In this case, the thermosetting resin is, for example, epoxy resin, phenol resin, maleimide resin, or polyester resin. The filler is an insulating ceramic having high thermal conductivity. For example, the filler is silicon oxide, aluminum oxide, boron nitride, or aluminum nitride. The content of the filler may be 10 volume % or more and 70 volume % or less with respect to the entire sealing member 50.

The semiconductor unit 2 includes an insulated circuit board 20 and the semiconductor chip 25 arranged on the front surface of the insulated circuit board 20 via solder 26. The insulated circuit board 20 is an example of a board, and includes an insulating plate 21, a plurality of conductive patterns 22 formed on the front surface of the insulating plate 21, and a metal plate 23 formed on the back surface of the insulating plate 21. The insulating plate 21 and the metal plate 23 have a rectangular shape in plan view. Furthermore, corner portions of the insulating plate 21 and the metal plate 23 may be R-chamfered or C-chamfered. The size of the metal plate 23 is smaller than the size of the insulating plate 21 in plan view, and the metal plate 23 is formed inside the insulating plate 21.

For example, the insulating plate 21 is a ceramic substrate. The ceramic substrate is made of a ceramic having good thermal conductivity. The ceramic is made of, for example, a material containing aluminum oxide, aluminum nitride, or silicon nitride as a main component. The insulating plate 21 has a rectangular shape in plan view.

The semiconductor chip 25 is arranged on an upper surface 22a of the conductive pattern 22. The conductive pattern 22 is formed over the entire surface of the insulating plate 21 except the edge portion thereof. Preferably, in plan view, an end portion of the conductive pattern 22 facing the outer periphery of the insulating plate 21 is arranged right over an end portion of the metal plate 23 on the outer peripheral side. Therefore, with the insulated circuit board 20, stress balance between the conductive pattern 22 and the metal plate 23 on the back surface of the insulating plate 21 is maintained. Damage, such as an excessive warp or a crack in the insulating plate 21, is suppressed. The conductive pattern 22 is made of a material having good electrical conductivity. For example, such a material is copper, aluminum, or an alloy containing at least one of them. The conductive pattern 22 may be plated with a material having good corrosion resistance. For example, such a material is nickel, a nickel-phosphorus alloy, or a nickel-boron alloy. A plating film has a thickness of 10 μm or less. The conductive pattern 22 on the insulating plate 21 is obtained by forming a metal plate on the front surface of the insulating plate 21 and performing treatment, such as etching, on the metal plate. Alternatively, the conductive pattern 22 cut out of a metal plate in advance may be bonded to the front surface of the insulating plate 21. The conductive pattern 22 included in the semiconductor device 1 of the present embodiment is simply an example. The number, shape, size, and the like of conductive patterns may be appropriately selected at need. The upper surface 22a of the conductive pattern 22 is also the upper surface 22a of the insulated circuit board 20.

A lower surface 23a of the metal plate 23 is arranged on the heat dissipation unit 4. The metal plate 23 is made of metal having good thermal conductivity. For example, such metal is copper, aluminum, or an alloy containing at least one of them. In this case, copper is contained. Furthermore, in order to improve corrosion resistance, the surface of the metal plate 23 may be plated. In this case, a plating material contains nickel. For example, such a plating material is nickel, a nickel-phosphorus alloy, or a nickel-boron alloy. A plating film has a thickness of 3 μm or more and 7 μm or less. The lower surface 23a of the metal plate 23 is also the lower surface 23a of the insulated circuit board 20. In addition, another form of a plating film formed on the metal plate 23 will be described in a second embodiment.

As the insulated circuit board 20 having the above structure, for example, a direct copper bonding (DCB) substrate or an active metal brazed (AMB) substrate may be used. Alternatively, a resin insulating substrate may be used. The insulated circuit board 20 conducts heat generated by the semiconductor chip 25, which will be described later, to the back surface side of the insulated circuit board 20 via the conductive pattern 22, the insulating plate 21, and the metal plate 23 to dissipate the heat.

The semiconductor chip 25 includes a switching element containing as a main component, for example, silicon. The switching element is, for example, a reverse-conducting (RC)-insulated gate bipolar transistor (IGBT). The RC-IGBT is a semiconductor element in which an IGBT and a free wheeling diode (FWD) are connected in inverse parallel in one chip.

The semiconductor chip 25 has a collector electrode as an input electrode on the back surface, and has a gate electrode as a control electrode and an emitter electrode as an output electrode on the front surface. The control electrode may be formed at the center of one side portion of the front surface of the semiconductor chip 25. Alternatively, the control electrode is not always formed at the center of one side portion of the front surface of the semiconductor chip 25, and may be shifted in the ±X direction from the center.

Another switching element may be a power metal-oxide-semiconductor field-effect transistor (MOSFET) containing, as a main component, silicon carbide. With the power MOSFET, a body diode may function as an FWD. In this case, the semiconductor chip 25 has, for example, an input electrode (drain electrode) as a main electrode on the back surface, and has an output electrode (source electrode) as a main electrode and a control electrode (gate electrode) on the front surface.

Furthermore, instead of the semiconductor chip 25, a semiconductor chip may be used which contains as a main component silicon and which includes a set of a switching element and a diode element. The switching element is, for example, a power MOSFET or an IGBT. A semiconductor chip including a switching element has, for example, an input electrode (a drain electrode of a power MOSFET or a collector electrode of an IGBT) as a main electrode on the back surface, and has a gate electrode as a control electrode and an output electrode (a source electrode of a power MOSFET or an emitter electrode of an IGBT) as a main electrode on the front surface. In addition, the diode element is, for example, a Schottky barrier diode (SBD) or a P-intrinsic-N (PiN) diode and is used as an FWD. The semiconductor chip including a diode element has an output electrode (cathode electrode) as a main electrode on the back surface and has an input electrode (anode electrode) as a main electrode on the front surface.

The back surface of the semiconductor chip 25 is bonded onto the conductive pattern 22 with solder 26. The solder 26 contains a solder component. The solder component is a substance contained in solder and includes lead-free solder containing a predetermined alloy as a main component. The predetermined alloy contains tin. Such an alloy is, for example, at least one of an alloy of tin-silver, an alloy of tin-silver-copper, an alloy of tin-zinc-bismuth, an alloy of tin-copper, an alloy of tin-silver-indium-bismuth, and an alloy of tin-antimony. Furthermore, such a solder component may contain an additive. For example, the additive is nickel, germanium, cobalt, or silicon. Therefore, for example, the solder components include not only tin but also at least one of silver, zinc, copper, bismuth, indium, and antimony. In addition, the solder component may include, for example, at least one of nickel, germanium, cobalt, and silicon. Solder components in the following embodiments are the same as those in the first embodiment. Moreover, a sintered body may be used instead of the solder 26. If a sintered body is used for bonding, then, for example, powder of silver, iron, copper, aluminum, titanium, nickel, tungsten, or molybdenum is used as a sintered material. In this case, the solder 26 is the same as solder 27 described later.

The case 3 includes a frame portion 31 and external connection terminals 32 buried in the frame portion 31. The frame portion 31 has a rectangular shape in plan view and has a frame shape surrounding a housing region 31f. The housing region 31f is a region that is open from an upper opening 31a on the front surface of the case 3 to a lower opening 31b on the back surface. The area of the upper opening 31a may be larger than the area of the lower opening 31b. The heat dissipation unit 4, which will be described later, is attached to a stepped portion in the back surface of the frame portion 31 to cover the housing region 31f.

In addition, an upper inner wall 31c of the frame portion 31 surrounds all sides of an upper portion of the housing region 31f, and forms the upper opening 31a communicating with the housing region 31f. A lower inner wall 31e of the frame portion 31 surrounds all sides of a lower portion of the housing region 31f, and forms the lower opening 31b communicating with the housing region 31f. In the frame portion 31, a stepped surface 31d is formed between the upper inner wall 31c and the lower inner wall 31e on each short side in plan view. The upper inner wall 31c is arranged approximately perpendicularly to the front surface of the frame portion 31. The stepped surface 31d is arranged approximately perpendicularly to the upper inner wall 31c. The lower inner wall 31e is arranged approximately perpendicularly to the stepped surface 31d. From the above description, in plan view, the lower inner wall 31e of the short side protrudes from the upper inner wall 31c toward the housing region 31f by the stepped surface 31d.

The frame portion 31 is formed by injection molding using a thermoplastic resin containing a filler. For example, such a resin is polyphenylene sulfide (PPS) resin, polybutylene terephthalate (PBT) resin, or polyamide (PA) resin. For example, the filler is glass fibers, glass beads, calcium carbide, talc, magnesium oxide, or aluminum hydroxide.

The external connection terminals 32 have a flat plate shape and are L-shaped in side view. The external connection terminals 32 are integrally molded with the frame portion 31. Each external connection terminal 32 includes an internal wiring portion 32a and an external wiring portion 32b formed approximately perpendicularly to the internal wiring portion 32a. The internal wiring portion 32a is included in the frame portion 31 in parallel to the front surface of the frame portion 31. One end portion of the internal wiring portion 32a extends approximately perpendicularly from the upper inner wall 31c toward the housing region 31f, and the front surface of the one end portion is exposed on the stepped surface 31d. The external wiring portion 32b is included in the frame portion 31 in approximately parallel to the upper inner wall 31c of the frame portion 31. The other end portion of the external wiring portion 32b extends approximately perpendicularly to the front surface of the frame portion 31. One end portion of the external wiring portion 32b is integrally connected to the other end portion of the internal wiring portion 32a in the frame portion 31.

The external connection terminals 32 are made of a material having good electrical conductivity. For example, such a material is copper, aluminum, or an alloy containing at least one of them. The thickness of the external connection terminals 32 is uniform over the entire external connection terminals 32. The external connection terminals 32 may be plated with a material having excellent corrosion resistance. Such a material is, for example, aluminum, nickel, titanium, chromium, molybdenum, tantalum, niobium, tungsten, vanadium, bismuth, zirconium, hafnium, gold, silver, platinum, palladium, or an alloy containing at least one of them.

An outer peripheral edge of the front surface of the heat dissipation unit 4 to which the semiconductor unit 2 is bonded is bonded to the back surface of the frame portion 31 of the case 3 on the lower opening 31b side with an adhesive (not illustrated). Thus, the semiconductor unit 2 is housed in the housing region 31f of the frame portion 31. A lid (not illustrated) may be bonded to the front surface of the frame portion 31 on the upper opening 31a side with an adhesive. This is not illustrated. For example, a thermosetting resin-based adhesive or an elastomer-based adhesive is used as the adhesive. The thermosetting resin-based adhesive contains, for example, epoxy resin or phenolic resin as a main component. The elastomer-based adhesive contains, for example, silicone rubber or chloroprene rubber as a main component.

A bonding region of each internal wiring portion 32a exposed on the stepped surface 31d is connected by a wiring member to either the conductive pattern 22 of the insulated circuit board 20 or the semiconductor chip 25. Wires 51 illustrated in FIG. 1 are examples of the wiring members. The wires 51 are made of a material having good electrical conductivity. For example, the material is gold, silver, copper, aluminum, or an alloy containing at least one of them. The wiring members are not limited to the wires 51, and lead frames may be used.

The heat dissipation unit 4 includes a heat dissipation base plate 40 and a plating film 41. The heat dissipation base plate 40 contains copper as a main component. Copper may be an example of a first metal material and may be contained in the first metal material. A front surface 40a of the heat dissipation base plate 40 includes an arrangement region 40b in which the lower surface 23a of the insulated circuit board 20 is arranged via the solder 27. The metal plate 23 of the insulated circuit board 20 is arranged in the arrangement region 40b of the heat dissipation base plate 40. The arrangement region 40b has a rectangular shape in plan view. This is the same with the insulated circuit board 20. The size of the arrangement region 40b may be equal to or smaller than the size of the insulating plate 21 and equal to or larger than the size of the metal plate 23 in plan view. In this case, the size of the arrangement region 40b is equal to the size of the metal plate 23. The thickness of the heat dissipation base plate 40 depends on the size of the semiconductor device 1, but may be, for example, 2.5 mm or more and 3.5 mm or less. The plating film 41 is an example of a first plating film, and is formed on the heat dissipation base plate 40 except an opening region 41a on the front surface 40a surrounding the entire outer periphery of the arrangement region 40b. The thickness of a portion of the plating film 41 except the opening region 41a is, for example, a commonly used thickness, and may be, for example, 1 μm or more and 10 μm or less.

The arrangement region 40b may have a rectangular shape in plan view. This is the same with the insulated circuit board 20. The arrangement region 40b is larger in size than the metal plate 23 of the insulated circuit board 20. The arrangement region 40b needs only include the insulated circuit board 20 in plan view, and does not always have a rectangular shape. In addition, corner portions of the arrangement region 40b are not always square in plan view, and may be rounded.

The arrangement region 40b may be recessed in the −Z direction with respect to the front surface 40a of the heat dissipation base plate 40 except the arrangement region 40b. In this case, the arrangement region 40b is smoothly connected to the front surface 40a of the heat dissipation base plate 40 except the arrangement region 40b. At this time, the depth of the deepest position of the arrangement region 40b may be deeper than the thickness of a plating film 24 described later. The arrangement region 40b may be flush with the front surface 40a of the heat dissipation base plate 40 except the arrangement region 40b.

The solder 27 is formed in the arrangement region 40b and the insulated circuit board 20 and the front surface 40a of the heat dissipation base plate 40 are bonded together therewith as illustrated in FIGS. 1 and 2. The thickness of the solder 27 is 100 μm or more and 500 μm or less. The solder 27 includes a fillet portion 27b extending to the outside of the lower surface 23a of the insulated circuit board 20 (metal plate 23) and formed outside the arrangement region 40b in plan view.

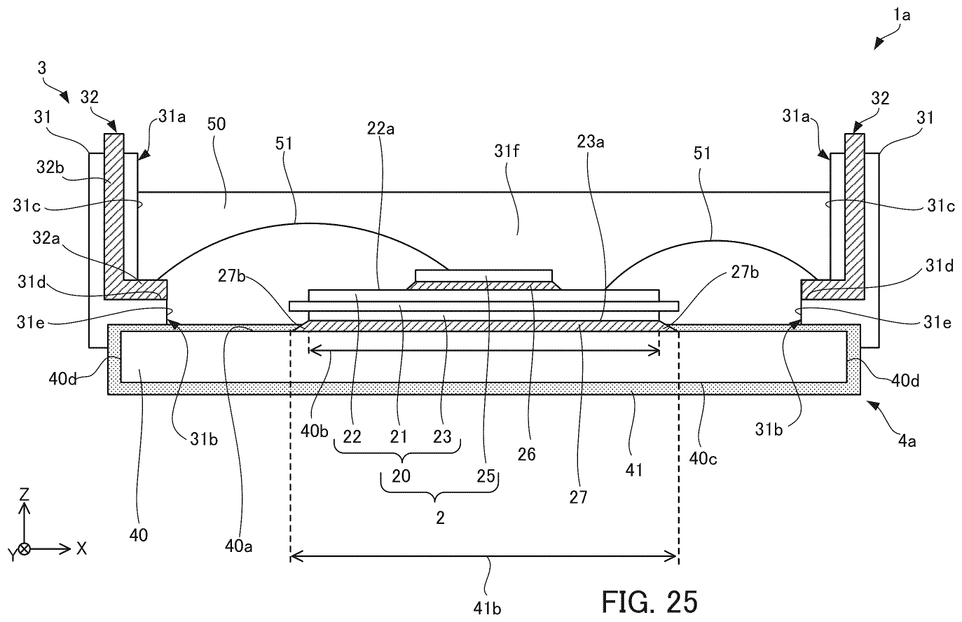

The fillet portion 27b (outer edge of the solder 27) may extend outside the outer edge of the insulated circuit board 20 (insulating plate 21) in plan view. However, the fillet portion 27b is preferably located inside the outer edge of the insulating plate 21. FIG. 2 simply illustrates a case where the outer edge of the solder 27 extends outside the outer edge of the insulated circuit board 20 (insulating plate 21) so that the position of the solder 27 with respect to the insulated circuit board 20 and the plating film 41 is clear. A region where the solder 27 spreads in this way on the arrangement region 40b of the front surface 40a of the heat dissipation base plate 40 is referred to as a solder region (reference sign is omitted and see a solder region 41b in FIG. 25). The size of the solder region is larger than the size of the arrangement region 40b in plan view, and the solder region may include the arrangement region 40b.

The opening region 41a of the plating film 41 around the arrangement region 40b includes a region where the plating film 41 is not formed, to account for the solder 27 spreading beyond the arrangement region 40b. The opening region 41a may have a rectangular shape. This is the same with the arrangement region 40b. The opening region 41a is larger than the arrangement region 40b. The opening region 41a is at least 1 mm larger than the arrangement region 40b on all sides. In addition, the opening region 41a may coincide with the solder region or may extend outside the solder region.

The plating film 41 is formed by plating on the surface of the heat dissipation base plate 40 except the arrangement region 40b. The plating film 41 improves the corrosion resistance of the heat dissipation base plate 40. A plating material of the plating film 41 may be a second metal material, and the second metal material contains nickel. For example, such a plating material is nickel, a nickel-phosphorus alloy, or a nickel-boron alloy.

Furthermore, a cooling unit (not illustrated) may be attached to the back surface of the case 3 including the heat dissipation unit 4 via a thermally conductive member. The thermally conductive member is a thermal interface material (TIM). The TIM is a general term for various materials such as thermally conductive grease, elastomer sheet, room temperature vulcanization (RTV) rubber, gel, a phase change material, solder, and silver solder. Thus, the heat dissipation property of the semiconductor device 1 is improved. In this case, the cooling unit is made of, for example, metal having good thermal conductivity. The metal is, for example, aluminum, iron, silver, copper, or an alloy containing at least one of them. In addition, the cooling unit is, for example, a heat sink including one or more fins or a cooling device by water cooling.

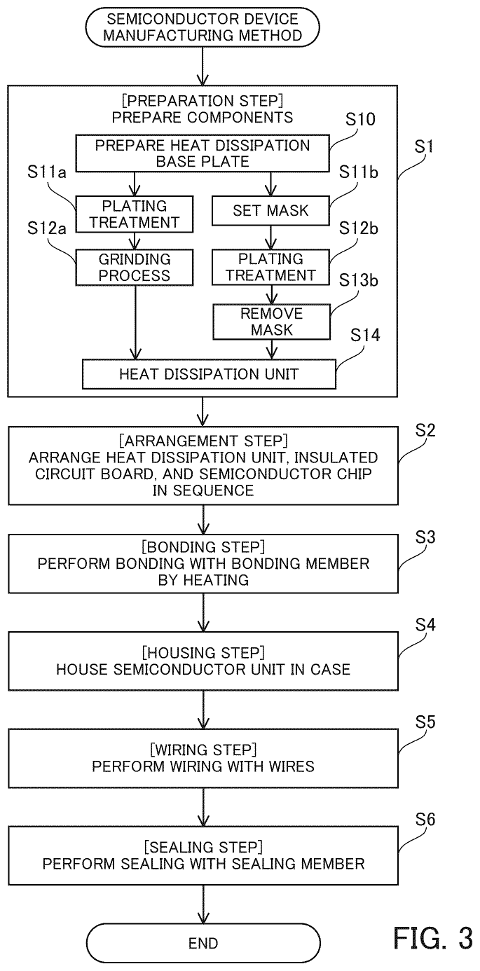

A method for manufacturing the semiconductor device 1 will now be described with reference to FIG. 3. FIG. 3 is a flowchart illustrative of a method for manufacturing the semiconductor device according to the first embodiment. The flowchart illustrative of the manufacturing method of FIG. 3 is simply an example. As long as the semiconductor device 1 includes the heat dissipation unit 4 to which the semiconductor unit 2 is bonded, the semiconductor device 1 may be manufactured by a method other than the method indicated by the flowchart of FIG. 3.

First, a preparation step for preparing components of the semiconductor device 1 is performed (step S1 in FIG. 3). In this case, the prepared components are, for example, the insulated circuit board 20, the semiconductor chip 25, the case 3, and the heat dissipation unit 4. In addition to these components, components needed as components of the semiconductor device 1 are prepared. Furthermore, a manufacturing apparatus used for manufacturing the semiconductor device 1 may also be prepared.

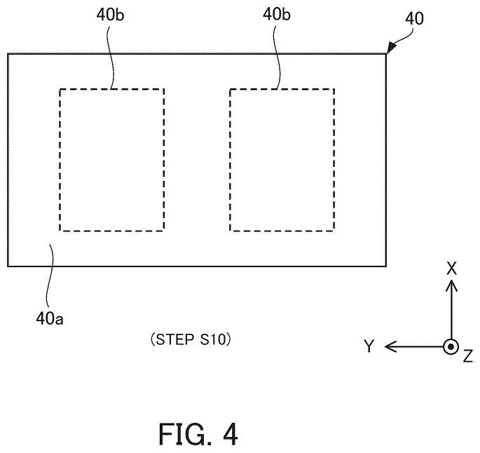

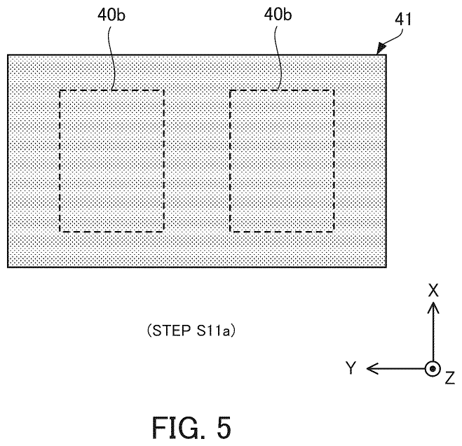

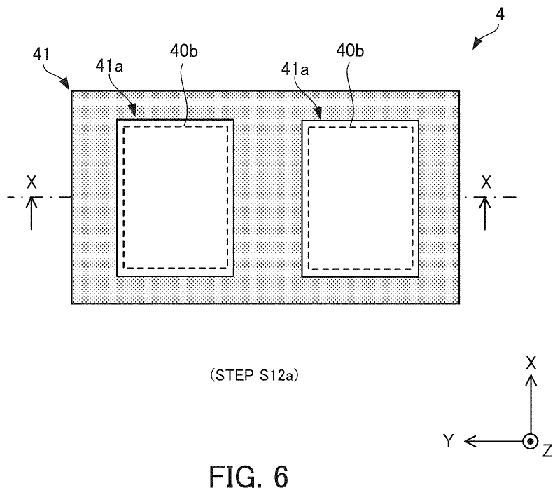

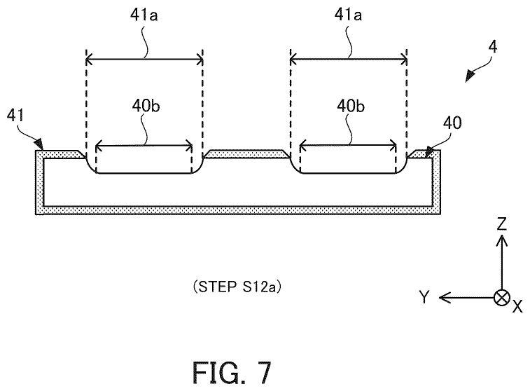

For example, two manufacturing methods are conceivable for the heat dissipation unit 4. First, a method for manufacturing the heat dissipation unit 4 included in the semiconductor device 1 illustrated in FIG. 1 (steps S10, S11a, S12a, and S14 in FIG. 3) will be described with reference to FIGS. 4 to 7. FIG. 4 is a plan view illustrative of a manufacturing step (preparing a heat dissipation base plate) of the heat dissipation unit included in the method for manufacturing the semiconductor device according to the first embodiment. FIG. 5 is a plan view illustrative of a manufacturing step (plating treatment) of the heat dissipation unit included in the method for manufacturing the semiconductor device according to the first embodiment. FIG. 6 is a plan view illustrative of a manufacturing step (grinding process) of the heat dissipation unit included in the method for manufacturing the semiconductor device of the first embodiment. FIG. 7 is a cross-sectional view illustrative of the manufacturing step (grinding process) of the heat dissipation unit included in the method for manufacturing the semiconductor device of the first embodiment. FIG. 7 is a cross-sectional view taken along the dot-dash line X-X in FIG. 6. FIG. 1 illustrates a case where the heat dissipation base plate 40 (heat dissipation unit 4) illustrated in FIGS. 4 to 7 is viewed in the +Y direction.

First, the heat dissipation base plate 40 is prepared (step S10 in FIG. 3). For example, a metal plate is sheared to obtain the heat dissipation base plate 40 having a size corresponding to the heat dissipation unit 4 of the semiconductor device 1, as illustrated in FIG. 4. For the shearing, for example, a press or a blade may be used. The heat dissipation base plate 40 has the shape of a flat plate which is rectangular in plan view. The front surface 40a of the heat dissipation base plate 40 is substantially smooth. Furthermore, the arrangement regions 40b are set on the front surface 40a of the heat dissipation base plate 40. Each arrangement region 40b is an arrangement region in which the metal plate 23 of the insulated circuit board 20 is arranged. The arrangement regions 40b are set according to the number of the insulated circuit boards 20 included in the semiconductor device 1. In this case, two arrangement regions 40b are set side by side on the front surface 40a of the heat dissipation base plate 40.

Next, the heat dissipation base plate 40 is plated (step S11a in FIG. 3). As illustrated in FIG. 5, plating treatment is performed on the entire surface including the front surface 40a of the heat dissipation base plate 40 to form the plating film 41. The plating treatment is a generally known method, and may be, for example, an electrolytic plating method or an electroless plating method.

Next, a grinding process is performed on the heat dissipation base plate 40 on which the plating film 41 is formed (step S12a in FIG. 3). The plating film 41 corresponding to the opening region 41a including the arrangement region 40b of the heat dissipation base plate 40 on which the plating film 41 is formed is removed by grinding. As illustrated in FIG. 6, the plating film 41 is removed to form an opening region 41a larger than the arrangement region 40b. The plating film 41 is formed on the heat dissipation base plate 40 except the opening region 41a. When the plating film 41 corresponding to the opening region 41a including the arrangement region 40b of the heat dissipation base plate 40 is removed by grinding, the plating film 41 on the arrangement region 40b is removed, and the front surface 40a of the heat dissipation base plate 40 in the arrangement region 40b is also ground. Therefore, as illustrated in FIG. 7, the arrangement region 40b is recessed from the front surface 40a except the arrangement region 40b. Furthermore, when the front surface 40a of the heat dissipation base plate 40 is ground, the bottom surface of the recess and the front surface 40a are connected by a smooth surface. Thus, the heat dissipation unit 4 illustrated in FIG. 1 is prepared (step S14 in FIG. 3).

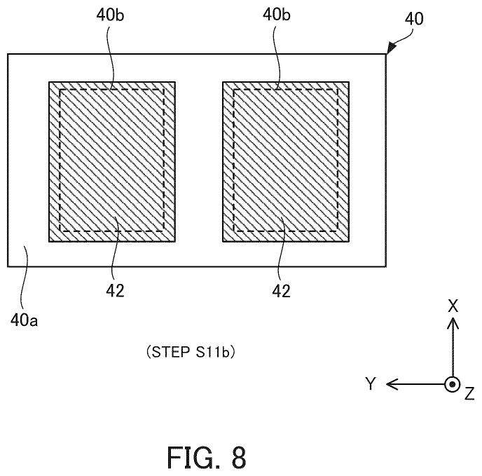

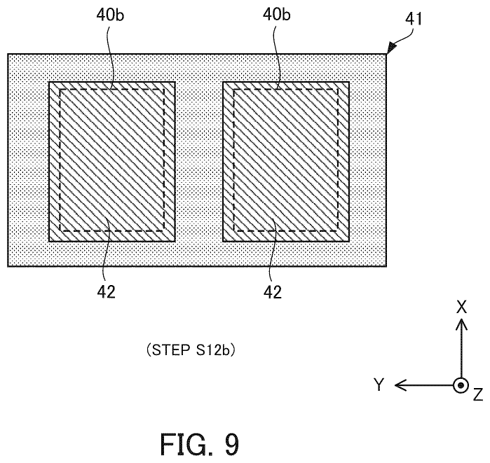

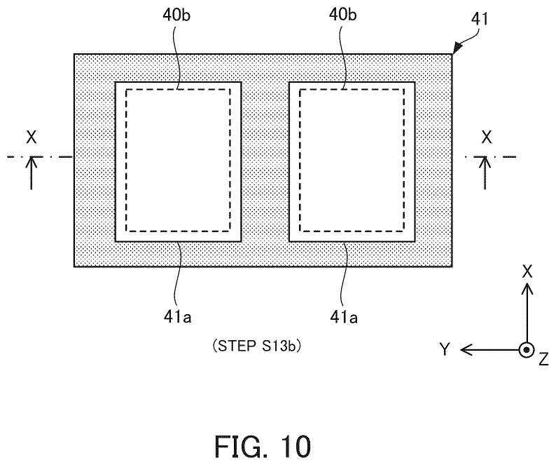

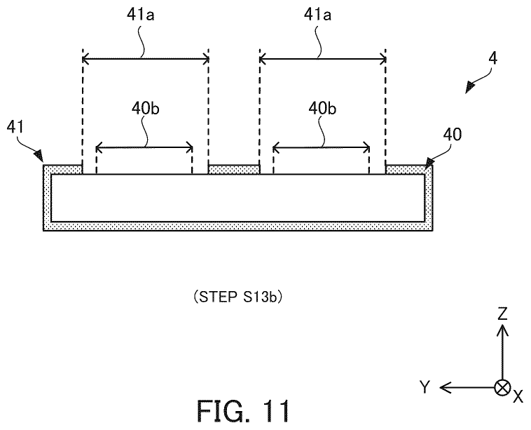

In addition, the heat dissipation unit 4 is also manufactured by the following manufacturing method. In this case, the manufacturing method (steps S10, S11b, S12b, S13b, and S14 in FIG. 3) will be described with reference to FIGS. 8 to 11, together with FIG. 4. FIG. 8 is a plan view illustrative of a manufacturing step (setting a mask) of the heat dissipation unit included in the method for manufacturing the semiconductor device according to the first embodiment. FIG. 9 is a plan view illustrative of a manufacturing step (plating treatment) of the heat dissipation unit included in the method for manufacturing the semiconductor device according to the first embodiment. FIG. 10 is a plan view illustrative of a manufacturing step (removing the mask) of the heat dissipation unit included in the method for manufacturing the semiconductor device according to the first embodiment. FIG. 11 is a cross-sectional view illustrative of the manufacturing step (removing the mask) of the heat dissipation unit included in the method for manufacturing the semiconductor device according to the first embodiment. FIG. 11 is a cross-sectional view taken along the dot-dash line X-X in FIG. 10.

In this case, first, the heat dissipation base plate 40 is also prepared (step S10 in FIG. 3). Step S10 is described above. Next, a mask is set on the heat dissipation base plate 40 (step S11b in FIG. 3). As illustrated in FIG. 8, a mask 42 is set in the arrangement region 40b of the front surface 40a of the heat dissipation base plate 40. The mask 42 set in the arrangement region 40b is equal in shape to the arrangement region 40b in plan view, and is a size larger than the arrangement region 40b.

Next, the heat dissipation base plate 40 is plated (step S12b in FIG. 3). Plating treatment is performed on the entire surface including the front surface 40a of the heat dissipation base plate 40 to form the plating film 41. This is the same with step S11a. On the front surface 40a of the heat dissipation base plate 40, the plating film 41 is formed in an area except the mask 42.

Next, the mask 42 is removed (step S13b in FIG. 3). After step S12b, the mask 42 is removed. As illustrated in FIG. 10, the plating film 41 is formed in an area of the front surface 40a of the heat dissipation base plate 40 other than the opening region 41a including the arrangement region 40b. Furthermore, as illustrated in FIG. 11, the arrangement region 40b of the front surface 40a of the heat dissipation base plate 40 is not ground, and the arrangement region 40b is flush with the front surface 40a. Thus, the heat dissipation unit 4 illustrated in FIG. 1 is prepared (step S14 in FIG. 3).

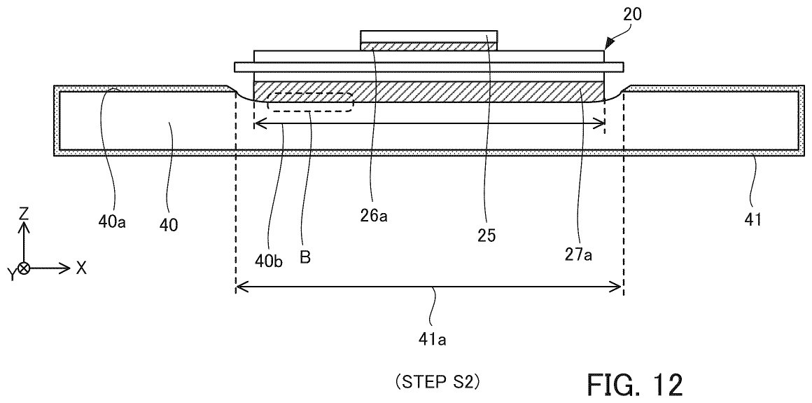

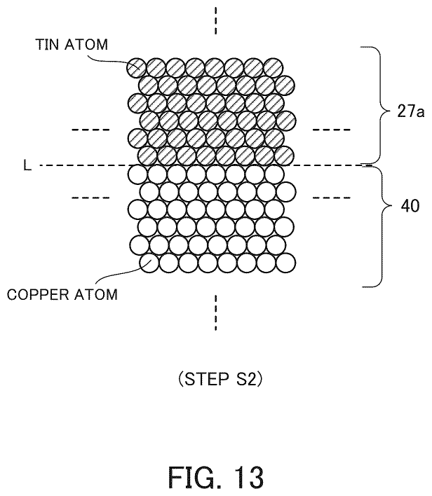

Next, an arrangement step for arranging the heat dissipation unit 4, the insulated circuit board 20, and the semiconductor chip 25 in sequence is performed (step S2 in FIG. 3). The arrangement step will be described with reference to FIGS. 12 and 13. FIG. 12 is a cross-sectional view illustrative of the arrangement step included in the method for manufacturing the semiconductor device according to the first embodiment. FIG. 13 is a schematic cross-sectional view illustrative of the arrangement of atoms in the arrangement step included in the method for manufacturing the semiconductor device according to the first embodiment. FIG. 13 schematically illustrates the arrangement of atoms in area B surrounded by a broken line in FIG. 12. Furthermore, FIG. 13 simply schematically illustrates the arrangement of atoms, and the number of stacked atoms does not always indicate the thickness of an atomic layer. In addition, in FIG. 13, only tin, which is a constituent element of the solder component, is illustrated. A solder component may contain an element other than tin, and the description of the element is omitted. Moreover, not only FIG. 13 but also the following schematic cross-sectional views illustrative of the arrangement of atoms illustrate only tin which is a constituent element of a solder component. In these schematic cross-sectional views, a solder component may also contain an element other than tin, and the description of the element is omitted.

The insulated circuit board 20 is arranged in the arrangement region 40b in the opening region 41a of the plating film 41 formed on the heat dissipation unit 4 via a solder plate 27a. The solder plate 27a is formed by hardening the solder 27 in the shape of a plate. The solder plate 27a is arranged at the bottom of the recess of the arrangement region 40b of the heat dissipation unit 4. The solder plate 27a may be equal in size to, for example, the lower surface 23a of the metal plate 23 of the insulated circuit board 20 in plan view.

The semiconductor chip 25 is arranged on the upper surface 22a of the conductive pattern 22 of the insulated circuit board 20 via a solder plate 26a. The solder plate 26a is formed by hardening the solder 26 in the shape of a plate. The solder plate 26a may be equal in size to, for example, the semiconductor chip 25 in plan view.

By the above arrangement step, as illustrated in FIG. 12, the insulated circuit board 20 is arranged in the arrangement region 40b of the heat dissipation unit 4 via the solder plate 27a. The semiconductor chip 25 is arranged on the conductive pattern 22 of the insulated circuit board 20 via the solder plate 26a.

Furthermore, area B in FIG. 12 is near the boundary between the heat dissipation base plate 40 in the heat dissipation unit 4 and the solder plate 27a. At the boundary in area B, as illustrated in FIG. 13, copper atoms contained in the heat dissipation base plate 40 and tin atoms contained in the solder plate 27a are regularly arranged with the boundary L in between. The boundary L corresponds to the boundary between the solder plate 27a and the arrangement region 40b of the heat dissipation base plate 40 when the solder plate 27a is arranged in the arrangement region 40b of the heat dissipation unit 4 (heat dissipation base plate 40). Since the solder plate 27a is not bonded at the stage of being placed on the heat dissipation base plate 40, an air layer included in the irregularities of the solder plate 27a exists between the solder plate 27a and the metal plate 23 and between the solder plate 27a and the heat dissipation base plate 40. The description thereof is omitted.

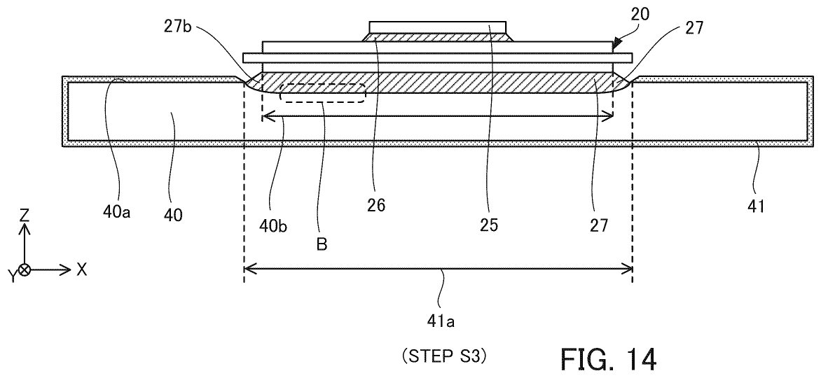

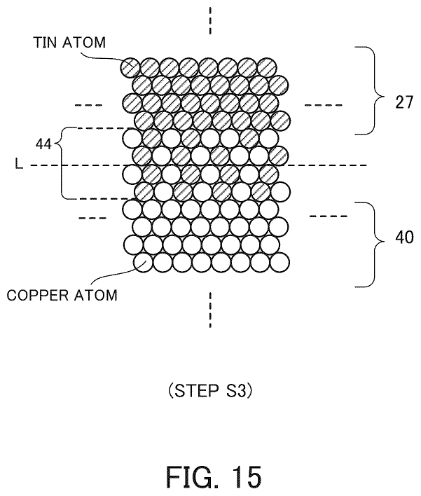

Next, a step for bonding the heat dissipation unit 4 and the insulating circuit board 20 and bonding the insulated circuit board 20 and the semiconductor chip 25 is performed (step S3 in FIG. 3). The bonding step will be described with reference to FIGS. 14 and 15. FIG. 14 is a cross-sectional view illustrative of a bonding step included in the method for manufacturing the semiconductor device according to the first embodiment. FIG. 15 is a schematic cross-sectional view illustrative of the arrangement of atoms in the bonding step included in the method for manufacturing the semiconductor device according to the first embodiment. FIG. 15 schematically illustrates the arrangement of atoms in area B surrounded by a broken line in FIG. 14. Furthermore, FIG. 15 simply schematically illustrates the arrangement of atoms and the number of stacked atoms does not always indicate the thickness of an atomic layer.

The solder plate 27a between the heat dissipation unit 4 and the insulated circuit board 20 and the solder plate 26a between the conductive pattern 22 of the insulated circuit board 20 and the semiconductor chip 25 arranged in step S2 are heated. The solder plates 26a and 27a melt and make the transition to the solder 26 and the solder 27 respectively.

When heating is performed in this way, as illustrated in FIG. 15, copper atoms in the heat dissipation base plate 40 move and diffuse into tin atoms in the solder 27 beyond the boundary L. Furthermore, tin atoms in the solder 27 diffuse into copper atoms in the heat dissipation base plate 40 beyond the boundary L by the diffusion of the copper atoms. Thus, an alloy layer 44 is formed near the boundary L. The alloy layer 44 contains copper atoms and tin atoms. The alloy layer 44 is included in the boundary between the solder 27 and the heat dissipation base plate 40 and is not limited to area B.

The solder 26 and the solder 27 obtained in this way by melting the solder plates 26a and 27a respectively are cooled and hardened. As a result, as illustrated in FIG. 14, the insulated circuit board 20 is bonded to the arrangement region 40b of the heat dissipation unit 4 via the hardened solder 27. In addition, similarly, the semiconductor chip 25 is bonded to the upper surface 22a of the insulated circuit board 20 via the hardened solder 26.

Therefore, the semiconductor unit 2 including the insulated circuit board 20 and the semiconductor chip 25 is formed. In addition, the semiconductor unit 2 is bonded to the arrangement region 40b of the heat dissipation unit 4 with the solder 27.

Next, a housing step for attaching the heat dissipation unit 4 to the lower opening 31b of the case 3 to house the semiconductor unit 2 in the case 3 is performed (step S4 in FIG. 3). An outer peripheral edge of the heat dissipation unit 4 is attached to the stepped portion on the back surface of the case 3 (frame portion 31) via an adhesive (not illustrated). Thus, the semiconductor unit 2 is housed in the housing region 31f of the case 3.

Next, a wiring step for wiring the semiconductor unit 2 housed in the case 3 is performed (step S5 in FIG. 3). The internal wiring portion 32a of one of the external connection terminals 32 exposed from the upper opening 31a of the case 3 and the conductive pattern 22 are connected by the wire 51. Furthermore, the output electrode of the semiconductor chip 25 and the internal wiring portion 32a of the other external connection terminal 32 are connected by the wire 51.

Next, a sealing step for sealing the inside of the housing region 31f of the case 3 with the sealing member 50 is performed (step S6 in FIG. 3). The inside of the housing region 31f is filled with the sealing member 50 from the upper opening 31a of the case 3 to seal the semiconductor unit 2 on the heat dissipation unit 4 in the housing region 31f. Thus, the semiconductor device 1 illustrated in FIG. 1 is obtained.

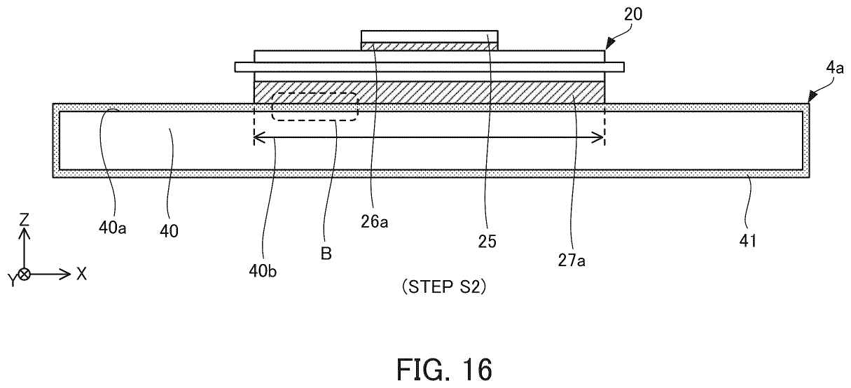

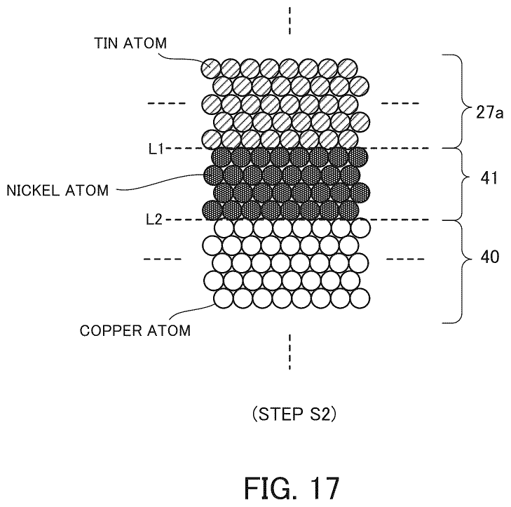

A semiconductor device (not illustrated) taken as a reference example for the semiconductor device 1 according to the first embodiment will be described with reference to FIG. 3 (and FIGS. 16 and 17 described later). The semiconductor device (not illustrated) taken as a reference example also includes a heat dissipation unit 4a. With a heat dissipation base plate 40 included in the heat dissipation unit 4a of the semiconductor device taken as a reference example, a plating film 41 is formed on the entire surface including an arrangement region 40b. That is, the plating film 41 in the arrangement region 40b of the heat dissipation unit 4a is not removed. The semiconductor device including the heat dissipation unit 4a is also manufactured according to the flowchart of FIG. 3.

First, a preparation step for preparing components of the semiconductor device is performed (step S1 in FIG. 3). The heat dissipation unit 4a prepared in the preparation step is manufactured through steps S10, S11a, and S14 in FIG. 3. Alternatively, it is manufactured through steps S10, S12b, and S14 of FIG. 3.

Next, an arrangement step for arranging the heat dissipation unit 4a, an insulated circuit board 20, and a semiconductor chip 25 in sequence is performed (step S2 in FIG. 3). The arrangement step will be described with reference to FIGS. 16 and 17. FIG. 16 is a cross-sectional view illustrative of the arrangement step included in a method for manufacturing the semiconductor device taken as a reference example. FIG. 17 is a schematic cross-sectional view illustrative of the arrangement of atoms in the arrangement step included in the method for manufacturing the semiconductor device taken as a reference example. FIG. 17 schematically illustrates the arrangement of atoms in area B surrounded by a broken line in FIG. 16. Furthermore, FIG. 17 simply schematically illustrates the arrangement of atoms and the number of stacked atoms does not always indicate the thickness of an atomic layer. In addition, in this case, since a solder plate 27a is not bonded at the stage of being placed on the heat dissipation base plate 40 (plating film 41), an air layer included in the irregularities of the solder plate 27a exists between the solder plate 27a and a metal plate 23 and between the solder plate 27a and the plating film 41, but the description thereof is omitted.

As illustrated in FIG. 16, the insulated circuit board 20 is arranged in the arrangement region 40b of the heat dissipation unit 4a, in which the plating film 41 is formed, via the solder plate 27a. Further, the semiconductor chip 25 is arranged on an upper surface 22a of a conductive pattern 22 of the insulated circuit board 20 via a solder plate 26a. The thickness of the plating film 41 formed on the entire surface of the heat dissipation base plate 40 is a commonly used thickness. This is the same with the first embodiment. The thickness of the plating film 41 may be, for example, 1 μm or more and 10 μm or less.

Furthermore, area B in FIG. 16 is near the boundary between the heat dissipation base plate 40 in the heat dissipation unit 4a on which the plating film 41 is formed and the solder plate 27a. At the boundaries in area B, as illustrated in FIG. 17, copper atoms contained in the heat dissipation base plate 40, nickel atoms contained in the plating film 41, and tin atoms contained in the solder plate 27a are regularly arranged with boundaries L1 and L2, respectively, in between. The boundary L1 corresponds to the boundary between the solder plate 27a and the plating film 41 when the solder plate 27a is arranged in the arrangement region 40b of the heat dissipation unit 4a (heat dissipation base plate 40). Similarly, the boundary L2 corresponds to the boundary between the heat dissipation base plate 40 and the plating film 41.

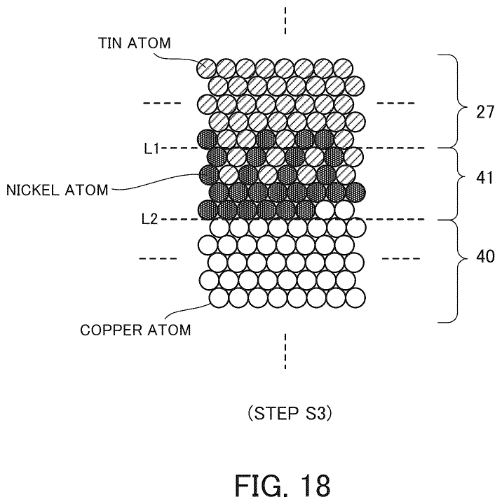

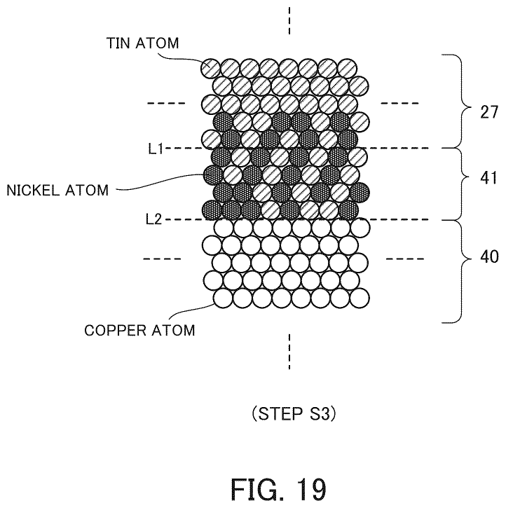

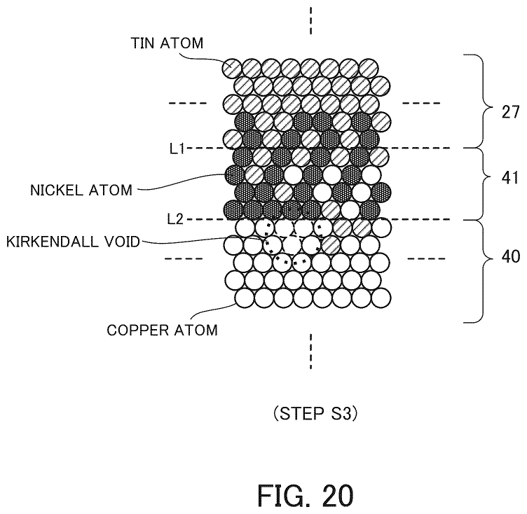

Next, a step for bonding the heat dissipation unit 4a and the insulated circuit board 20 and bonding the insulated circuit board 20 and the semiconductor chip 25 is performed (step S3 in FIG. 3). The bonding step will be described with reference to FIGS. 18 to 20. FIG. 18 is a first schematic cross-sectional view illustrative of the arrangement of atoms in the bonding step (at heating time) included in the method for manufacturing the semiconductor device taken as a reference example. FIG. 19 is a second schematic cross-sectional view illustrative of the arrangement of atoms in the bonding step (at heating time) included in the method for manufacturing the semiconductor device taken as a reference example. FIG. 20 is a third schematic cross-sectional view illustrative of the arrangement of atoms in the bonding step (at heating time) included in the method for manufacturing the semiconductor device taken as a reference example. FIGS. 18 to 20 schematically illustrate the arrangement of atoms in area B surrounded by a broken line in FIG. 16 and changes from FIG. 17. FIGS. 18 to 20 simply schematically illustrate the arrangement of atoms and the number of stacked atoms does not always indicate the thickness of an atomic layer.

The solder plate 27a between the heat dissipation unit 4a and the insulated circuit board 20 and the solder plate 26a between the conductive pattern 22 of the insulated circuit board 20 and the semiconductor chip 25 arranged in step S2 are heated. The solder plates 26a and 27a melt and make the transition to solder 26 and the solder 27 respectively.

When the solder plates 26a and 27a are heated in this way, as illustrated in FIG. 18, nickel atoms in an arbitrary portion of the plating film 41 move and diffuse into tin atoms of the molten solder 27 beyond the boundary L1. On the other hand, tin atoms in an arbitrary portion of the solder 27 diffuse into nickel atoms of the plating film 41 beyond the boundary L1. Therefore, the formation of an alloy layer containing nickel atoms and tin atoms starts near the boundary L1.

When the heating is continued, the diffusion of nickel atoms in the plating film 41 into the solder 27 and the diffusion of tin atoms in the solder 27 into the plating film 41 proceed and, as illustrated in FIG. 19, the formation of an alloy layer containing nickel atoms and tin atoms near the boundary L1 further proceeds. The plating film 41 is thinner than the solder 27. Therefore, in the plating film 41, nickel atoms partially decrease and tin atoms partially increase. Nickel atoms in the plating film 41 are partially replaced in this way with tin atoms and solder erosion occurs. If the plating film 41 is sufficiently thin, the plating film 41 disappears when all the nickel atoms in the plating film 41 are replaced with tin atoms.

When the heating is further continued, copper atoms in the heat dissipation base plate 40 having a high diffusion speed move beyond the boundary L2, move through a portion of the plating film 41 where the solder erosion has occurred, and diffuse into the solder 27. In addition, tin atoms of the solder 27 near the boundary L1 diffuse into the heat dissipation base plate 40 beyond the boundary L2. At this time, as illustrated in FIG. 20, traces of the movement of copper atoms in the heat dissipation base plate 40 become vacancies (Kirkendall voids). The Kirkendall voids are often generated in a portion of the heat dissipation base plate 40 under the remaining plating film 41.

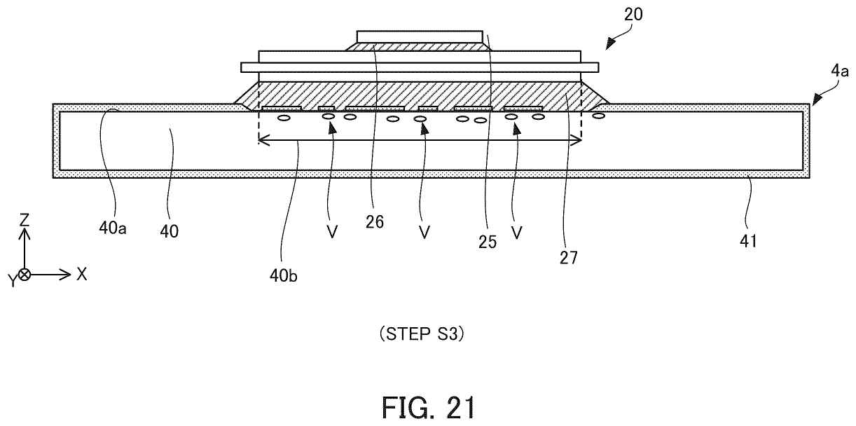

After the heating, the molten solder 26 and solder 27 are hardened by cooling. Bonding the heat dissipation unit 4a and the insulated circuit board 20 and bonding the insulated circuit board 20 and the semiconductor chip 25 performed in this way will be described with reference to FIG. 21. FIG. 21 is a cross-sectional view illustrative of a bonding step (after bonding) included in the method for manufacturing the semiconductor device taken as a reference example.

The molten solder 26 and solder 27 are cooled and hardened in this way. As a result, as illustrated in FIG. 21, the insulated circuit board 20 is bonded to the arrangement region 40b of the heat dissipation unit 4a via the hardened solder 27. Furthermore, similarly, the semiconductor chip 25 is bonded to the upper surface 22a of the insulated circuit board 20 via the hardened solder 26. However, a plurality of Kirkendall voids (vacancies V) are included in the heat dissipation base plate 40.

Next, a housing step (step S4 in FIG. 3) for attaching the heat dissipation unit 4a to the lower opening 31b of the case 3 to house the semiconductor unit 2 in the case 3 and a wiring step (step S5 in FIG. 3) for wiring the semiconductor unit 2 housed in the case 3 are performed in sequence. Finally, a sealing step for sealing the inside of the housing region 31f of the case 3 with a sealing member 50 is performed (step S6 in FIG. 3). As a result, the semiconductor device including the heat dissipation unit 4a is manufactured.

With the heat dissipation unit 4a, as described with reference to FIG. 20, the plating film 41 right under the solder 27 is partially eroded (eroded by the solder 27). Furthermore, as illustrated in FIG. 21, a plurality of Kirkendall voids (vacancies V) are generated under the partially remaining plating film 41 of the heat dissipation base plate 40. When the plurality of Kirkendall voids (vacancies V) are included in the heat dissipation base plate 40, the thermal resistance of the heat dissipation base plate 40 increases. In addition, in this case, the following is described. Kirkendall voids are generated in the heat dissipation unit 4a (heat dissipation base plate 40) due to the heating in the bonding step. In addition to this case, the Kirkendall voids are also generated by heat generation due to long-term operation of the semiconductor device 1. With the semiconductor device including the heat dissipation unit 4a, a heat dissipation property deteriorates.

Therefore, the above semiconductor device 1 includes the insulated circuit board 20 including the lower surface 23a, the heat dissipation base plate 40 including the front surface 40a and having the arrangement region 40b in which the lower surface 23a of the insulated circuit board 20 is arranged on the front surface 40a via the solder 27, the plating film 41 formed on the front surface 40a of the heat dissipation base plate 40 except the solder region 41b in which the solder 27 spreads on the arrangement region 40b of the front surface 40a, and the alloy layer 44 included between the solder 27 and the arrangement region 40b of the heat dissipation base plate 40 and containing a solder component contained in the solder 27. In particular, with the semiconductor device 1, the plating film 41 is formed on the entire surface of the heat dissipation base plate 40 except the opening region 41a surrounding the outer periphery of the arrangement region 40b in which the insulated circuit board 20 is arranged via the solder 27. That is, the solder 27 for bonding the insulated circuit board 20 is bonded to the heat dissipation base plate 40 without interposing the plating film 41. Therefore, in the arrangement region 40b of the heat dissipation base plate 40, the plating film 41 is not eroded by the solder 27. As a result, atoms constituting the heat dissipation base plate 40 do not move, and generation of vacancies in the heat dissipation base plate 40 is suppressed. Further, even when heat is generated due to long-term operation of the semiconductor device 1, generation of vacancies is also suppressed. As a result, an increase in the thermal resistance of the heat dissipation base plate 40 is suppressed and deterioration in the heat dissipation property of the semiconductor device 1 including the heat dissipation base plate 40 is suppressed. In addition, deterioration in the reliability of the semiconductor device 1 is also prevented.

### Second Embodiment

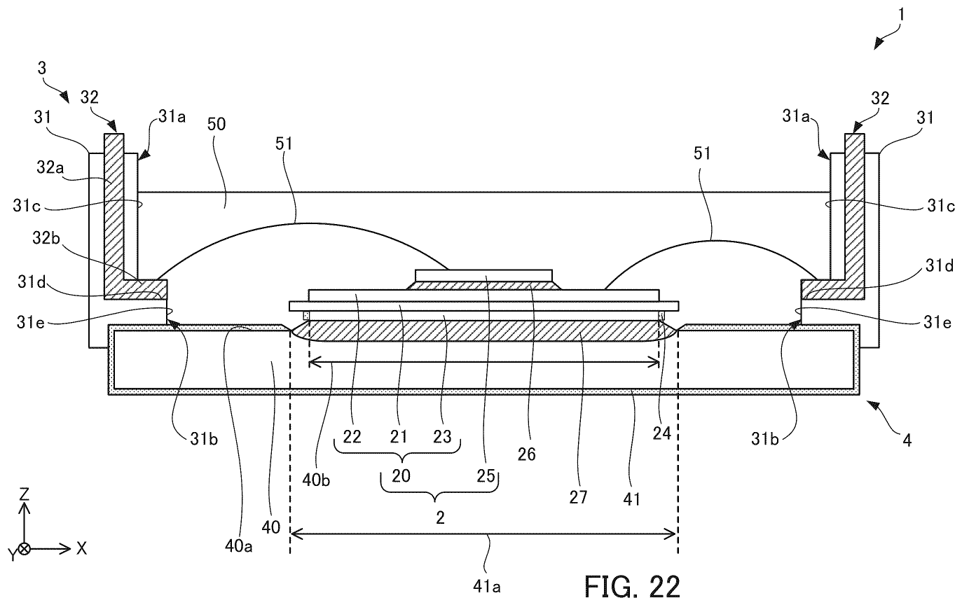

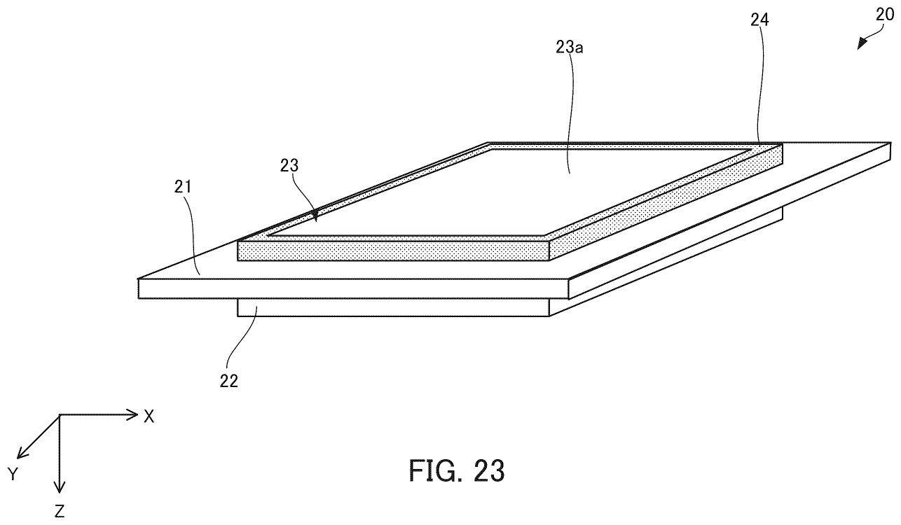

In a second embodiment, a case where in a semiconductor device 1, a plating film is not formed on a lower surface 23a of an insulated circuit board 20 with which solder 27 is in contact will be described with reference to FIGS. 22 and 23. FIG. 22 is a cross-sectional view of a semiconductor device according to the second embodiment. FIG. 23 is a rear perspective view of an insulated circuit board included in the semiconductor device according to the second embodiment.

As described in the first embodiment, the surface of a metal plate 23 of an insulated circuit board 20 of the semiconductor device 1 may be plated to improve corrosion resistance. The insulated circuit board 20 is bonded to an arrangement region 40b of a heat dissipation unit 4 via solder 27. The plated metal plate 23 comes into contact with the solder 27 via a plating film. For this reason, with the metal plate 23, solder erosion also occurs in the plating film.

Therefore, as illustrated in FIGS. 22 and 23, the metal plate 23 of the insulated circuit board 20 of the semiconductor device 1 according to the second embodiment has a plating film 24 formed on the surface except the lower surface 23a. That is, the metal plate 23 does not have the plating film 24 on the lower surface 23a arranged in the arrangement region 40b of the heat dissipation base plate 40 via the solder 27, and the plating film 24 is formed on a side surface so as to surround the entire periphery of the lower surface 23a except the lower surface 23a.

Therefore, the solder 27 for bonding the heat dissipation unit 4 is bonded to the metal plate 23 of the insulated circuit board 20 without interposing the plating film 24. As a result, the plating film 24 is not eroded by the solder 27 on the lower surface 23a of the metal plate 23. Therefore, atoms constituting the metal plate 23 do not move and generation of vacancies in the metal plate 23 is suppressed. Further, even when heat is generated due to long-term operation of the semiconductor device 1, generation of vacancies is also suppressed. As a result, an increase in the thermal resistance of the heat dissipation unit 4 and the metal plate 23 is suppressed, deterioration in the heat dissipation property of the semiconductor device 1 including the heat dissipation unit 4 and the metal plate 23 is suppressed, and deterioration in the reliability of the semiconductor device 1 is also prevented.

### Third Embodiment

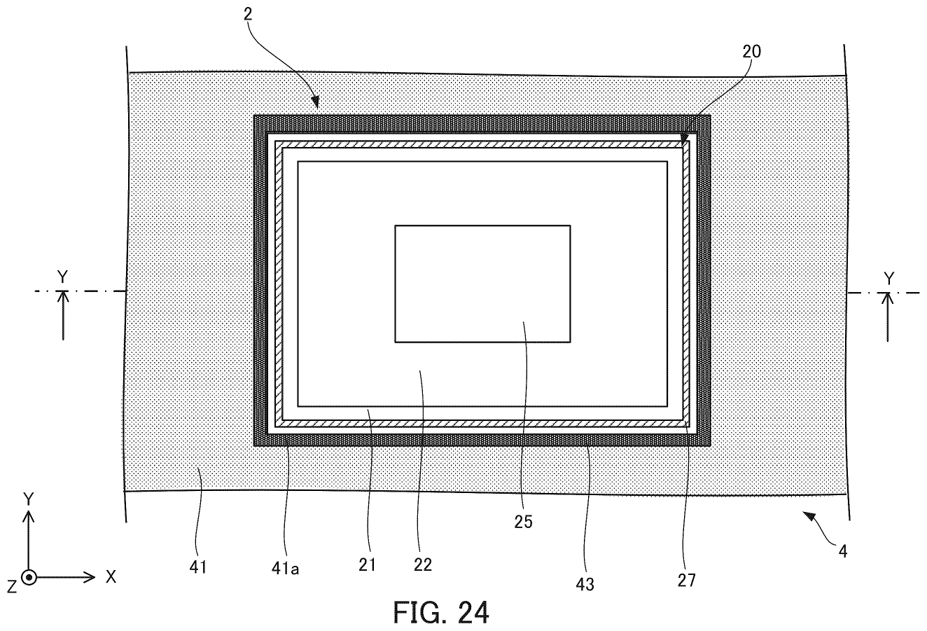

A heat dissipation unit 4 in a third embodiment will be described with reference to FIG. 24. FIG. 24 is a plan view of a principal part of a semiconductor device according to a third embodiment (without a sealing member). The heat dissipation unit 4 in the third embodiment is included in the semiconductor device 1 according to the first embodiment.

A resist film 43 is continuously formed in a loop shape along an opening edge portion of an opening region 41a of a plating film 41 included in the heat dissipation unit 4 in the third embodiment. For example, the resist film 43 is epoxy resin or acrylic resin.

Although solder 27 formed between an arrangement region 40b of a heat dissipation base plate 40 and the insulated circuit board 20 may spread outside the arrangement region 40b, the resist film 43 suppresses the spread of the solder 27. If there is no resist film 43 and the solder 27 spreads outside the arrangement region 40b, the solder 27 may reach the plating film 41 around the arrangement region 40b. If the solder 27 comes into contact with the plating film 41, as described above, vacancies are generated in the heat dissipation base plate 40 under the plating film 41. By forming the resist film 43 on the opening edge portion of the opening region 41a of the plating film 41, it is possible to suppress the generation of vacancies in the heat dissipation base plate 40. Furthermore, the opening region 41a may be narrowed by the resist film 43. A region on the heat dissipation base plate 40 where neither the plating film 41 nor the solder 27 is included may be reduced or eliminated.

The resist film 43 may be formed along the opening edge portion of the opening region 41a of the plating film 41 by application after performing steps S10, S11a, and S12a of FIG. 3. Alternatively, after step S11a, the resist film 43 may be formed along the opening edge portion of the opening region 41a of the plating film 41 and step S12a may be performed.

Further, the resist film 43 may be formed along the opening edge portion of the opening region 41a of the plating film 41 by application after performing steps S10, S11b, S12b, and S13b of FIG. 3.

### Fourth Embodiment

A semiconductor device according to a fourth embodiment has the same structure as the semiconductor device 1 according to the first embodiment except a heat dissipation unit 4a. The semiconductor device according to the fourth embodiment will be described with reference to FIG. 25. FIG. 25 is a cross-sectional view illustrative of the semiconductor device according to the fourth embodiment. FIG. 25 corresponds to FIG. 1 of the first embodiment.

As illustrated in FIG. 25, a semiconductor device 1a includes a semiconductor unit 2, a heat dissipation unit 4a having a front surface on which the semiconductor unit 2 is arranged, and a case 3 which is formed on an outer edge portion of the heat dissipation unit 4a and which houses the semiconductor unit 2. The inside of the case 3 of the semiconductor device 1a is sealed by a sealing member 50. The semiconductor unit 2, the case 3, and the sealing member 50 have the same structure as those in the first embodiment have. Furthermore, solder 26 and solder 27 formed on an upper surface 22a and a lower surface 23a, respectively, of the semiconductor unit 2 are also as described in the first embodiment.

The heat dissipation unit 4a includes a heat dissipation base plate 40 and a plating film 41. The heat dissipation base plate 40 is made of the same material as that in the first embodiment and has the same size as that of the heat dissipation base plate 40 in the first embodiment. Furthermore, a front surface 40a of the heat dissipation base plate 40 also includes an arrangement region 40b which is the same as that in the first embodiment. The lower surface 23a of an insulated circuit board 20 is bonded to the arrangement region 40b via the solder 27. However, unlike the first embodiment, the arrangement region 40b of the front surface 40a of the heat dissipation base plate 40 in the fourth embodiment is not recessed in the −Z direction with respect to the front surface 40a of the heat dissipation base plate 40. That is, the entire front surface 40a of the heat dissipation base plate 40 in the fourth embodiment is approximately smooth. The front surface 40a of the heat dissipation base plate 40 includes a solder region 41b in which the solder 27 spreads on the arrangement region 40b.

The plating film 41 is made of the same material as that in the first embodiment. In addition, the plating film 41 is formed on the front surface 40a of the heat dissipation base plate 40 except the solder region 41b. Further, the plating film 41 is also formed on the entire surface of the heat dissipation base plate 40 except the front surface 40a. That is, the plating film 41 is formed on the front surface 40a except the solder region 41b of the heat dissipation base plate 40, a back surface 40c opposite to the front surface 40a, and four side surfaces 40d surrounding the front surface 40a and the back surface 40c.

Moreover, the thickness of the plating film 41 formed on the front surface 40a is smaller than the thickness of the plating film 41 formed on the back surface 40c and the side surfaces 40d. The thickness of the plating film 41 formed on the front surface 40a is, for example, 0.2 μm or less.

The insulated circuit board 20 is bonded to the solder region 41b of the heat dissipation base plate 40 included in the heat dissipation unit 4a via the solder 27. The plating film 41 is formed on the surface of the heat dissipation base plate 40 except the solder 27 (solder region 41b). Further, an alloy layer containing a solder component contained in the solder 27 is included between the solder 27 and the front surface 40a of the heat dissipation base plate 40. The details of the alloy layer will be described later.

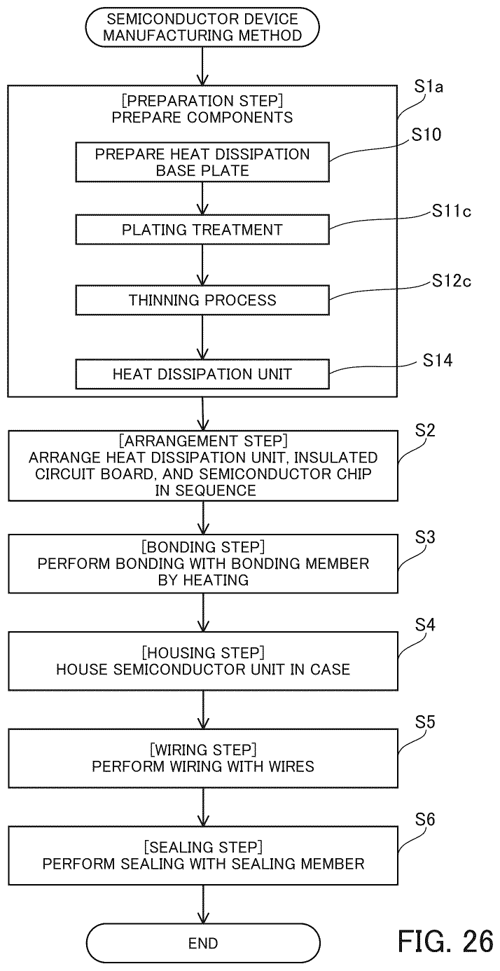

Next, a method for manufacturing the semiconductor device 1a will be described with reference to FIG. 26. FIG. 26 is a flowchart illustrative of a method for manufacturing the semiconductor device according to the fourth embodiment. The flowchart of FIG. 6 illustrative of the manufacturing method is simply an example. As long as the semiconductor device 1a includes the heat dissipation unit 4a to which the semiconductor unit 2 is bonded, the semiconductor device 1a is manufactured by a method other than the method indicated by the flowchart of FIG. 26. In addition, steps after step S1 in the flowchart of FIG. 26 are the same as those after step S1 in the flowchart of FIG. 3. Therefore, the description of the steps after step S1 may be simplified.

First, a preparation step for preparing components of the semiconductor device 1a is performed (step S1a in FIG. 26). The prepared components are, for example, the insulated circuit board 20, the semiconductor chip 25, the case 3, and the heat dissipation unit 4a. In addition to these components, components needed as component of the semiconductor device 1a are prepared. Furthermore, a manufacturing apparatus used for manufacturing the semiconductor device 1a may also be prepared.

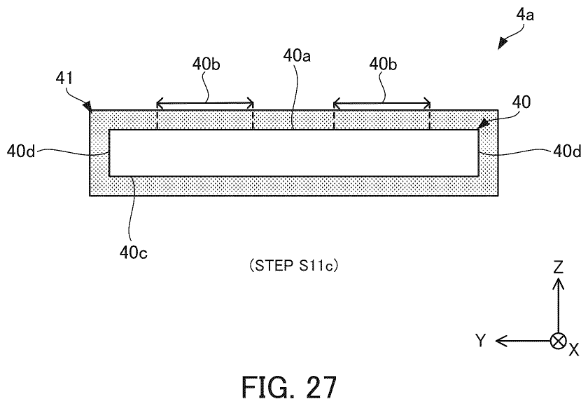

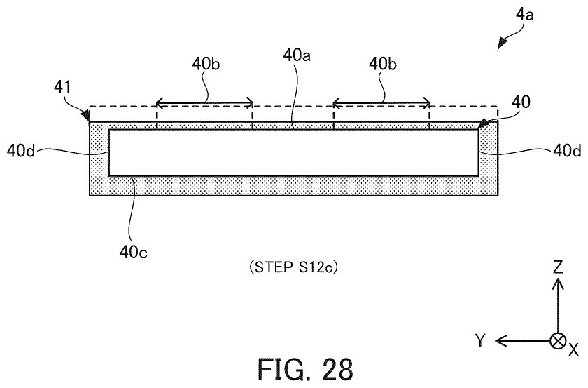

A method for manufacturing the heat dissipation unit 4a included in the semiconductor device 1a illustrated in FIG. 25 (steps S10, S11c, S12c, and S14 in FIG. 26) will now be described with reference to FIGS. 4, 27, and 28. FIG. 27 is a cross-sectional view illustrative of a manufacturing step (plating treatment) of the heat dissipation unit included in the method for manufacturing the semiconductor device according to the fourth embodiment. FIG. 28 is a cross-sectional view illustrative of a manufacturing step (thinning process) of the heat dissipation unit included in the method for manufacturing the semiconductor device according to the fourth embodiment. FIGS. 27 and 28 correspond to a cross-sectional portion taken along the dot-dash line X-X in FIG. 6.

First, the heat dissipation base plate 40 is prepared (step S10 in FIG. 26). This is the same with the first embodiment. Next, plating treatment is performed on the entire surface of the heat dissipation base plate 40 to form a plating film 41 (step S11c in FIG. 26). For example, as illustrated in FIG. 27, plating treatment is performed on the front surface 40a, the back surface 40c, and the side surfaces 40d of the heat dissipation base plate 40 to form the plating film 41. The plating treatment is a generally known method, and may be, for example, an electrolytic plating method or an electroless plating method. The plating film 41 formed on the entire surface of the heat dissipation base plate 40 may have the same thickness. In this case, the thickness may be, for example, 1 μm or more and 10 μm or less.

Next, the plating film 41 on the front surface 40a of the heat dissipation base plate 40 is thinned by a thinning process (step S12c in FIG. 26). Of the plating film 41 formed on the surface of the heat dissipation base plate 40, the plating film 41 on the front surface 40a is uniformly ground as a whole. As illustrated in FIG. 28, the plating film 41 on the front surface 40a of the heat dissipation base plate 40 becomes thinner than the plating film 41 on the other surfaces and the thickness thereof is 0.2 μm or less. Thus, the heat dissipation unit 4a is prepared (step S14 in FIG. 26).

Furthermore, the heat dissipation unit 4a may also be manufactured by the following method. For example, in the plating treatment of step S11c of FIG. 26, the plating treatment may be performed so that the thickness of the plating film 41 formed on the front surface 40a of the heat dissipation base plate 40 is smaller than the thickness of the plating film 41 formed on the other surfaces.

Further, in the above description, a case where the entire plating film 41 on the front surface 40a of the heat dissipation base plate 40 is made thinner than the plating film 41 on the other surfaces has been described as an example. However, another case is also possible. Only the solder region 41b of the plating film 41 formed on the front surface 40a of the heat dissipation base plate 40 may be thinned. That is to say, the plating film 41 is formed on the entire surface of the heat dissipation base plate 40 in the same way as in step S11c described above, and only the plating film 41 in the solder region 41b is ground and thinned in step S12c.

Alternatively, the plating film 41 having a thickness of at least 0.2 μm may be formed on the entire surface of the heat dissipation base plate, a mask may be set on the solder region 41b of the plating film 41, the plating film 41 may be further formed, and the mask may be removed. In this case, the plating film 41 having a desired thickness is also formed on the heat dissipation base plate 40 by the electrolytic plating method or the electroless plating method. By doing so, only the solder region 41b of the plating film 41 formed on the front surface 40a of the heat dissipation base plate 40 is made thinner than the other portions.

Furthermore, the thickness of the plating film 41 formed on the entire surface of the heat dissipation base plate 40 including the solder region 41b may be 0.2 μm or less. In this case, the plating film 41 having a desired thickness is also formed on the heat dissipation base plate 40 by the electrolytic plating method or the electroless plating method.

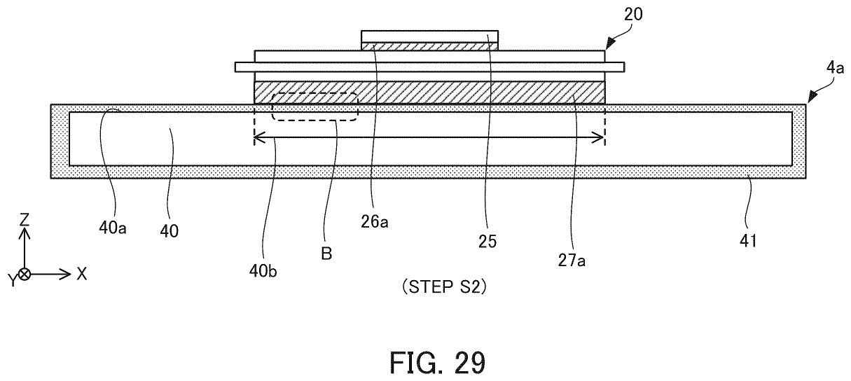

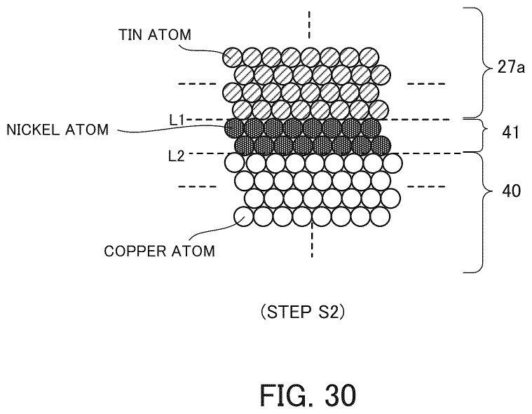

Next, an arrangement step for arranging the heat dissipation unit 4a, the insulated circuit board 20, and the semiconductor chip 25 in sequence is performed (step S2 in FIG. 26). The arrangement step will be described with reference to FIGS. 29 and 30. FIG. 29 is a cross-sectional view illustrative of the arrangement step included in the method for manufacturing the semiconductor device according to the fourth embodiment. FIG. 30 is a schematic cross-sectional view illustrative of the arrangement of atoms in the arrangement step included in the method for manufacturing the semiconductor device according to the fourth embodiment. FIG. 30 schematically illustrates the arrangement of atoms in area B surrounded by a broken line in FIG. 29. Furthermore, FIG. 30 simply schematically illustrates the arrangement of atoms and the number of stacked atoms does not always indicate the thickness of an atomic layer.

The insulated circuit board 20 is arranged in the arrangement region 40b of the plating film 41 formed on the heat dissipation unit 4a via a solder plate 27a. The solder plate 27a is formed by hardening the solder 27 in the shape of a plate. In this case, the solder plate 27a may be equal in size to, for example, the lower surface 23a of the metal plate 23 of the insulated circuit board 20 in plan view. This is the same with the first embodiment.

The semiconductor chip 25 is arranged on an upper surface 22a of a conductive pattern 22 of the insulated circuit board 20 via a solder plate 26a. The solder plate 26a is formed by hardening the solder 26 in the shape of a plate. The solder plate 26a may be equal in size to, for example, the semiconductor chip 25 in plan view.

By the above arrangement step, as illustrated in FIG. 29, the insulated circuit board 20 is arranged in the arrangement region 40b of the heat dissipation unit 4a via the solder plate 27a and the semiconductor chip 25 is arranged on the conductive pattern 22 of the insulated circuit board 20 via the solder plate 26a.

Furthermore, area B in FIG. 29 is near the boundary between the heat dissipation base plate 40 in the heat dissipation unit 4a and the solder plate 27a. At the boundary in area B, as illustrated in FIG. 30, tin atoms, which are a solder component contained in the solder plate 27a, and nickel atoms contained in the plating film 41 are regularly arranged with the boundary L1 in between. The boundary L1 corresponds to a boundary between the solder plate 27a and the plating film 41 when the solder plate 27a is arranged on the plating film 41. The boundary may contain a solder component, such as silver or zinc, in addition to tin. Hereinafter, only tin is described as a typical solder component, but another solder component may be contained.

Furthermore, nickel atoms contained in the plating film 41 and copper atoms contained in the heat dissipation base plate 40 are regularly arranged with a boundary L2 in between. The boundary L2 corresponds to a boundary between the plating film 41 and the arrangement region 40b of the heat dissipation base plate 40 when the plating film 41 is formed in the arrangement region 40b of the heat dissipation unit 4a (heat dissipation base plate 40).

Since the solder plate 27a is not bonded to the heat dissipation base plate 40 (the plating film 41) at the stage of being placed on the heat dissipation base plate 40, an air layer included in the irregularities of the solder plate 27a exists between the solder plate 27a and the metal plate 23 and between the solder plate 27a and the heat dissipation base plate 40 (plating film 41). However, the description thereof is omitted.

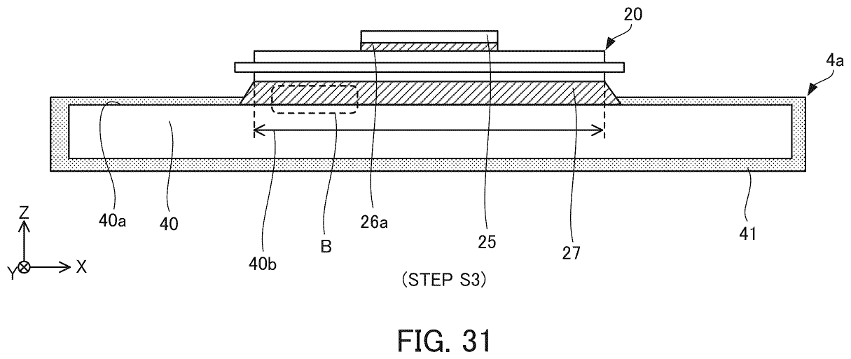

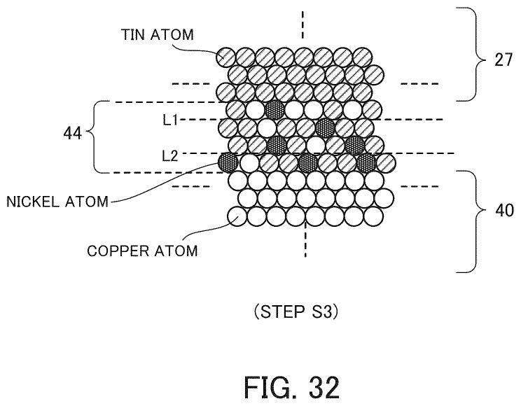

Next, a step for bonding the heat dissipation unit 4a and the insulated circuit board 20 and bonding the insulated circuit board 20 and the semiconductor chip 25 is performed (step S3 in FIG. 26). The bonding step will be described with reference to FIGS. 31 and 32. FIG. 31 is a cross-sectional view illustrative of the bonding step included in the method for manufacturing the semiconductor device according to the fourth embodiment. FIG. 32 is a schematic cross-sectional view illustrative of the arrangement of atoms in the bonding step included in the method for manufacturing the semiconductor device according to the fourth embodiment. FIG. 32 schematically illustrates the arrangement of atoms in area B surrounded by a broken line in FIG. 31. Furthermore, FIG. 32 simply schematically illustrates the arrangement of atoms, and the number of stacked atoms does not always indicate the thickness of an atomic layer.

The solder plate 27a between the heat dissipation unit 4a and the insulated circuit board 20 and the solder plate 26a between the conductive pattern 22 of the insulated circuit board 20 and the semiconductor chip 25 arranged in step S2 are heated. The solder plates 26a and 27a melt and make the transition to the solder 26 and the solder 27 respectively.

When heating is performed in this way, tin atoms in the molten solder 27 and nickel atoms in the molten plating film 41 move and diffuse beyond the boundary L1. In addition, copper atoms in the heat dissipation base plate 40 and nickel atoms in the plating film 41 move and diffuse beyond the boundary L2. Furthermore, tin atoms in the molten solder 27 move further and diffuse into copper atoms in the heat dissipation base plate 40 beyond the boundary L2. Furthermore, copper atoms in the heat dissipation base plate 40 move further and diffuse into tin atoms in the molten solder 27 beyond the boundary L1.

The plating film 41 on the front surface 40a of the heat dissipation base plate 40 is formed sufficiently thin. Therefore, nickel atoms in the plating film 41 are replaced by tin atoms and copper atoms and plating erosion occurs. As a result, as illustrated in FIG. 32, the plating film 41 is eroded between the solder 27 and the heat dissipation base plate 40 near the boundaries L1 and L2, and an alloy layer 44 is formed. At this time, traces of the movement of copper atoms in the heat dissipation base plate 40, such as those illustrated in FIG. 20, do not become vacancies (Kirkendall voids). The alloy layer 44 contains copper atoms, tin atoms, and nickel atoms. The alloy layer 44 may be included not only in area B but also in the boundary between the solder 27 and the heat dissipation base plate 40.

The molten solder 26 and the molten solder 27 are cooled and hardened. The insulated circuit board 20 is bonded to the arrangement region 40b of the heat dissipation unit 4a (to the front surface 40a of the heat dissipation base plate 40) via the hardened solder 27. Similarly, the semiconductor chip 25 is bonded to the upper surface 22a of the insulated circuit board 20 via the hardened solder 26.

Therefore, the semiconductor unit 2 including the insulated circuit board 20 and the semiconductor chip 25 is formed. Further, the semiconductor unit 2 is bonded to the arrangement region 40b of the heat dissipation unit 4a by the solder 27.

Thereafter, a housing step (step S4 in FIG. 26), a wiring step (step S5 in FIG. 26), and a sealing step (step S6 in FIG. 26) in the flowchart are performed in sequence. This is the same with the first embodiment. Thus, the semiconductor device 1a illustrated in FIG. 25 is obtained.

In the above semiconductor device 1a, the insulated circuit board 20 and the heat dissipation base plate 40 having the plating film 41 on the front surface 40a are also bonded to each other by the solder plate 27a. Therefore, the plating film 41 is eroded in the arrangement region 40b of the heat dissipation base plate 40. That is, the plating film 41 on the front surface 40a of the heat dissipation base plate 40 of the semiconductor device 1a is sufficiently thinner than the plating film 41 in the semiconductor device taken as a reference example, which is illustrated in FIG. 16, and disappears at the time of bonding. Therefore, the alloy layer 44 containing atoms constituting the heat dissipation base plate 40, tin atoms constituting the solder 27, and nickel atoms constituting the plating film 41 is formed and generation of vacancies in the heat dissipation base plate 40 is suppressed. Further, even when heat is generated due to long-term operation of the semiconductor device 1a, generation of vacancies is also suppressed. As a result, an increase in the thermal resistance of the heat dissipation base plate 40 is suppressed and deterioration in the heat dissipation property of the semiconductor device 1a including the heat dissipation base plate 40 is suppressed. In addition, deterioration in the reliability of the semiconductor device 1a is also prevented.

According to the disclosed techniques, deterioration in a heat dissipation property is prevented and deterioration in reliability is suppressed.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a board having a lower surface;
a heat dissipation base plate having a principal surface that includes
an arrangement region in which the lower surface of the board is arranged via a solder, and
a solder region in which the solder spreads over the arrangement region;
a first plating film on the principal surface of the heat dissipation base plate, except for the solder region; and
an alloy layer disposed between the solder and the heat dissipation base plate in the arrangement region, the alloy layer containing a solder component.

2. The semiconductor device according to claim 1, wherein the alloy layer further contains a first metal material that is contained in the heat dissipation base plate, in addition to the solder component.

3. The semiconductor device according to claim 2, wherein the first metal material contains copper.

4. The semiconductor device according to claim 2, wherein the alloy layer further contains a second metal material that constitutes the first plating film, in addition to the solder component and the first metal material.

5. The semiconductor device according to claim 4, wherein the second metal material contains nickel.

6. The semiconductor device according to claim 4, wherein:
the first plating film is further disposed on a surface of the heat dissipation base plate other than the principal surface; and
a thickness of the first plating film on the principal surface is less than a thickness of the first plating film on the surface of the heat dissipation base plate other than the principal surface.

7. The semiconductor device according to claim 4, wherein a thickness of the first plating film on the principal surface is less than 0.2 μm.

8. The semiconductor device according to claim 1, wherein the first plating film contains nickel as a main component.

9. The semiconductor device according to claim 1, wherein an outer periphery of the arrangement region is located entirely inside an outer periphery of the board in a plan view of the semiconductor device.

10. The semiconductor device according to claim 1, wherein the first plating film is disposed on the principal surface of the heat dissipation base plate except for an opening region in which the solder region is located, the opening region surrounding an entire outer periphery of the solder region.

11. The semiconductor device according to claim 10, wherein the arrangement region is recessed with respect to a region of the principal surface other than the arrangement region.

12. The semiconductor device according to claim 11, wherein the solder includes a fillet portion extending outside the lower surface of the board in a plan view of the semiconductor device.

13. The semiconductor device according to claim 12, wherein an outer peripheral edge of the fillet portion of the solder is located outside the arrangement region in the plan view.

14. The semiconductor device according to claim 10, wherein:
the board includes:
an insulating plate;
a conductive pattern on a front surface of the insulating plate; and
a metal plate formed on a back surface of the insulating plate and having a back surface that forms the lower surface of the board; and
the semiconductor device further includes a second plating film on side surfaces of the metal plate except for the lower surface thereof so as to surround an entire outer periphery of the lower surface.

15. The semiconductor device according to claim 14, wherein the metal plate contains copper as a main component.

16. The semiconductor device according to claim 14, wherein the second plating film contains nickel as a main component.

17. The semiconductor device according to claim 10, further comprising a resist material surrounding an entire outer periphery of the opening region of the first plating film disposed on the principal surface of the heat dissipation base plate.
